(19) United States
(12) Patent Application Publication
(10) Pub. No.: US 2016/0049609 A1
(43) Pub. Date: Feb. 18, 2016

(54) METHOD FOR MANUFACTURING GAS BARRIER FILM, GAS BARRIER FILM AND ELECTRONIC DEVICE

(71) Applicant: KONICA MINOLTA, INC., Tokyo (JP)

(72) Inventor: Hidetoshi Ezure, Tokyo (JP)

(73) Assignee: Konica Minolta, Inc., Tokyo (JP)

(21) Appl. No.: 14/782,221

(22) PCT Filed: Apr. 1, 2014
(86) PCT No.: PCT/JP2014/059607

§ 371 Date: Oct. 2, 2015

(30) Foreign Application Priority Data
Apr. 2, 2013 (JP) 2013-076756

(51) Int. Cl. H01L 51/52; C23C 16/48; C23C 16/50

(52) U.S. Cl. CPC H01L 51/5246; C23C 16/50; C23C 16/48

(57) ABSTRACT

A method for producing a gas barrier film includes forming a smoothing layer on one surface of a resin substrate; and forming a gas barrier layer containing a carbon atom, a silicon atom and an oxygen atom on a surface of the smoothing layer. The surface of the smoothing layer is controlled to have a dispersion component of a surface free energy in the range of 30 to 40 mN/m at an environment of 23° C. and 50% RH. The gas barrier layer is formed employing a raw material gas containing an organic silicon compound and an oxygen gas with a discharge plasma chemical vapor deposition method having a discharge space between rollers applied with a magnetic field.

### TECHNICAL FIELD

The present invention relates generally to a gas barrier film and a method for producing the same, and an electronic device employing the same. More specifically, the present invention relates to a gas barrier film mainly used for an electronic device such as an organic electroluminescent element (hereafter, it is called as an organic EL element) and a method for producing the same, and an electronic device employing the same gas barrier film.

### BACKGROUND

In the past, a gas barrier film, which is formed by laminating a plurality of layers containing a thin film of a metal oxide such as aluminum oxide, magnesium oxide, or silicon oxide on a surface of a plastic substrate or film, has been widely used for a package of an article required for blocking of a variety of gases such as water vapor and oxygen, for example, for a package application to prevent deterioration of foods, industrial products and medicines.

A gas barrier film has been requested to be used for a flexible electronic device such as solar battery element, an organic EL element, and a liquid crystal element provided with flexibility, in addition to a package application. However, with respect to these flexible electronic devices, it is required an extremely high gas barrier property comparable to a glass substrate level. At present time, it has not been achieved a gas barrier film having sufficient performance.

As a method for producing such a gas barrier film, it has been known a gas phase method such as: a chemical deposition method (a plasma CVD method: Chemical Vapor Deposition) in which an organic silicon compound represented by tetraethoxy silane (hereafter, it is abbreviated as TEOS) is used for forming a film on a substrate by oxidizing with oxygen plasma under a reduced pressure; or a physical deposition method (a vacuum deposition method and a sputter method) in which metal Si is vaporized with a semi-conductor laser, and then deposited on a substrate under the presence of oxygen.

Patent document 1 discloses a production method for producing a gas barrier laminate film having a water vapor permeability of 1×10⁻⁴ g/m²·24 h level with a roll to roll method by using a plasma CVD apparatus as shown in FIG. 2. A gas barrier film produced with a method described in Patent document 1 has been improved in adhesion property with a substrate and flexibility by applying a plasma CVD method which enabled to arrange carbon atoms at the periphery of the substrate. However, it was found that its gas barrier property, adhesion property and flexibility for an electronic device such as an organic EL element were insufficient when used under the severe conditions of high temperature and high humidity such as an outdoor usage.

On the other hand, Patent document 2 discloses a production method of a gas barrier layer with applying a coating method having advantageous properties of productivity and cost. The method described in Patent document 2 is a method using a polysilazane as an inorganic precursor compound. This compound is coated and dried, then the formed coating layer is irradiated with vacuum ultraviolet rays (hereafter, it is also called as a VUV ray) to form a gas barrier layer. In addition, Patent document 3 discloses a gas barrier film provided with a gas barrier layer produced with an atomic layer deposition method (ALD) on a substrate having a planarized coating layer employing a reactive diluting agent. The methods described in Patent documents 2 and 3 don't refer to the combination with a plasma CVD method or the effects obtained by this combination.

### PRIOR ART DOCUMENTS

### Patent Documents

Patent document 1: WO 2012/046767
Patent document 2: JP-A 2011-143577
Patent document 3: JP-A 2011-518055

### SUMMARY OF THE INVENTION

One or more embodiments of the present invention provide a production method of a gas barrier film having a gas barrier property required for an electronic device application under the using condition of high temperature and high humidity such as an outdoor usage, as well as having high flexibility and excellent adhesion property. One or more embodiments of the present invention also provide a gas barrier film and an electronic device using the same.

The present inventors have found out a production method of a gas barrier film. According to one or more embodiments, the method comprises the steps of: forming a smoothing layer on one surface of a resin substrate, the smoothing layer having a surface free energy within a specific range at an environment of 23° C. and 50% RH; and forming a gas barrier layer containing a carbon atom, a silicon atom and an oxygen atom as constituting elements on a surface of the smoothing layer with a discharge plasma chemical vapor phase deposition method using a film forming gas containing an organic silicon compound as a raw material gas and an oxygen gas. By using this method, it can realize a production method of a gas barrier film having a gas barrier property required for an electronic device application under the using condition of high temperature and high humidity such as an outdoor usage, as well as having high flexibility and excellent adhesion property. Thus, the present invention has been achieved.

One or more embodiments of the present invention can be realized by the following means.

1. A method for producing a gas barrier film comprising the steps of:

forming a smoothing layer on one surface of a resin substrate; and

forming a gas barrier layer containing a carbon atom, a silicon atom and an oxygen atom on a surface of the smoothing layer,

wherein the surface of the smoothing layer is controlled to have a dispersion component of a surface free energy in the range of 30 to 40 mN/m at an environment of 23° C. and 50% RH; and

the gas barrier layer is formed employing a raw material gas containing an organic silicon compound and an oxygen gas with a discharge plasma chemical vapor deposition method having a discharge space between rollers applied with a magnetic field.

2. The method for producing a gas barrier film described in the item 1,

wherein the gas barrier layer is formed so as to satisfy all of the following conditions (1) to (4),

(1) A carbon atomic ratio of the gas barrier layer is continuously changed in a thickness direction in relation to a distance from a surface of the gas barrier layer within a distance range of 89% from the surface of the gas barrier layer when a thickness of the gas barrier layer in a vertical direction is set to be 100%.
(2) A maximum value of the carbon atomic ratio of the gas barrier layer in the thickness direction is less than 20 at % within the distance range of 89% from the surface of the gas barrier layer when the thickness of the gas barrier layer in a vertical direction is set to be 100%.
(3) A carbon atomic ratio of the gas barrier layer is continuously increased in the thickness direction within the distance range of 90 to 95% from the surface of the gas barrier layer when the thickness of the gas barrier layer in a vertical direction is set to be 100%.
(4) A maximum value of the carbon atomic ratio of the gas barrier layer in the thickness direction is 20 at % or more within the distance range of 90 to 95% from the surface of the gas barrier layer when the thickness of the gas barrier layer in a vertical direction is set to be 100%.
3. The method for producing a gas barrier film described in the items 1 or 2,

wherein the smoothing layer is formed by coating a composition containing a resin having a radical reactive unsaturated bond, an inorganic particle, a photo-initiator, a solvent, and a reactive diluting agent; and

a ratio of the reactive diluting agent in the smoothing layer is in the range of 0.1 to 10 mass %.

4. The method for producing a gas barrier film described in any one of the items 1 to 3,

wherein a second gas barrier layer is formed by coating a polysilazane containing liquid on the gas barrier layer, followed by drying to form a coated film, then the coated film is subjected to a reforming treatment by irradiating with vacuum ultraviolet rays having a wavelength of 200 nm or less.

5. A gas barrier film comprising: a smoothing layer on one surface of a resin substrate; and a gas barrier layer containing a carbon atom, a silicon atom and an oxygen atom on a surface of the smoothing layer,

wherein a surface of the smoothing layer has a dispersion component of a surface free energy in the range of 30 to 40 mN/m at an environment of 23° C. and 50% RH; and

the gas barrier layer is formed employing a raw material gas containing an organic silicon compound and an oxygen gas with a discharge plasma chemical vapor deposition method having a discharge space between rollers applied with a magnetic field.

6. A gas barrier film described in the item 5, satisfying all of the following conditions (1) to (4).
(1) A carbon atomic ratio of the gas barrier layer is continuously changed in a thickness direction in relation to a distance from a surface of the gas barrier layer within a distance range of 89% from the surface of the gas barrier layer when a thickness of the gas barrier layer in a vertical direction is set to be 100%.
(2) A maximum value of the carbon atomic ratio of the gas barrier layer in the thickness direction is less than 20 at % within the distance range of 89% from the surface of the gas barrier layer when the thickness of the gas barrier layer in a vertical direction is set to be 100%.
(3) A carbon atomic ratio of the gas barrier layer is continuously increased in the thickness direction within the distance range of 90 to 95% from the surface of the gas barrier layer when the thickness of the gas barrier layer in a vertical direction is set to be 100%.
(4) A maximum value of the carbon atomic ratio of the gas barrier layer in the thickness direction is 20 at % or more within the distance range of 90 to 95% from the surface of the gas barrier layer when the thickness of the gas barrier layer in a vertical direction is set to be 100%.
7. An electronic device provided with the gas barrier film described in the items 5 or 6.

One or more embodiments of the invention can provide a production method of a gas barrier film and a gas barrier film having a gas barrier property required for an electronic device application under the using condition of high temperature and high humidity such as an outdoor usage, as well as having high flexibility and excellent adhesion property.

A formation mechanism or an action mechanism of the effects of one or more embodiments of the present invention may be follows.

One or more embodiments of the present invention have been achieved by using a resin substrate provided with a smoothing layer having a dispersion component of a surface free energy to be in the range of 30 to 40 mN/m, and by applying a production method of a gas barrier film in which a gas barrier layer is formed with a roller space discharge plasma chemical vapor deposition method by impressing a magnetic field to the rollers. As a result, it was found that it can produce a gas barrier film having an extremely superior gas barrier property required for an electronic device application under the using condition of high temperature and high humidity such as an outdoor usage, as well as having high flexibility and excellent adhesion property.

First, as an action mechanism of improving an adhesion property, it is assumed as follows. A smoothing layer is formed on a surface of a resin substrate which is provided with a gas barrier layer by suitably selecting a composition containing a resin having a radical reactive unsaturated bond, an inorganic particle, a photo-initiator, a solvent, and a reactive diluting agent. Then, a gas barrier layer formed on the aforesaid smoothing layer with a roller space discharge plasma chemical vapor deposition method by impressing a magnetic field to the rollers. Consequently, it can arrange more amount of carbon atom component in the neighbor portion of the resin substrate. As a result, it is assumed that the adhesion property between the resin substrate (smoothing layer) and the gas barrier layer is improved.

In particular, when the aforesaid smoothing layer contains a reactive diluting agent in a specific range of amount, a portion of non-reactive and relatively strong polarity in the reactive diluting agent will be oriented to the aforesaid smoothing layer surface. The carbon atom component in the gas barrier layer having relatively near polarity will be arranged more to the side of the aforesaid smoothing layer with a specific plasma chemical vapor deposition method, and will be bonded. As a result, it is supposed that the adhesion property is improved.

Regarding to the flexibility and gas barrier property, it is supposed that the effects are caused by continuous change of density gradient of carbon atom component in the formed gas barrier layer. In particular, the flexibility is caused by the arrangement in which more amount of carbon atom component is located to the surroundings of the aforesaid resin substrate. The carbon atom component has an effect of diffusing and relieving the stress from the resin substrate, and it is supposed that the excellent effect as described above will be exhibited under the severe environmental conditions.

In addition, by employing a plasma CVD method using a flat electrode (horizontal conveyance), it will not be produced a continuous change of density gradient of carbon atom component in the formed gas barrier layer and in the surroundings of the resin substrate. Consequently, it is difficult to achieve compatibility of adhesion property, flexibility and gas barrier property. The effect of one or more embodiments of the present invention is produced by the continuous change of density gradient of carbon atom component in the gas barrier layer formed with a roller space discharge plasma chemical vapor deposition method impressed with a magnetic field to the rollers. By this, it is possible to achieve compatibility of adhesion property, flexibility and gas barrier property.

Further, on the formed gas barrier layer as described above, a coated layer is formed by using a polysilazane containing liquid with a coating method. Subsequently, the coated layer is subject to a reforming treatment by irradiating with vacuum ultraviolet rays (VUV) to form a second gas barrier layer. It can bury the minute defects remaining in the gas barrier layer formed with a plasma CVD method with a gas barrier component of polysilazane from the upper part. It is supposed that an extremely superior gas barrier property and flexibility required for an electronic device can be exhibited even under high temperature and high humidity.

### BRIEF DESCRIPTION OF THE DRAWINGS

FIG. 1A is a schematic cross sectional drawing showing an example of a basic composition of a gas barrier film of one or more embodiments of the present invention.

FIG. 1B is a schematic cross sectional drawing showing an example of a basic composition of a gas barrier film of one or more embodiments of the present invention.

FIG. 2 is a schematic drawing showing an example of a producing method of a gas barrier film using a roller space discharge plasma CVD apparatus by impressing a magnetic field to the rollers.

FIG. 3 is a graph showing an example of a silicon distribution curve, an oxygen distribution curve, and a carbon distribution curve of a gas barrier layer of one or more embodiments of the present invention.

FIG. 4 is a graph showing an example of a silicon distribution curve, an oxygen distribution curve, and a carbon distribution curve of a gas barrier layer of a comparative example.

FIG. 5 is a schematic drawing showing an electronic device provided with a gas barrier film.

### DETAILED DESCRIPTION OF EMBODIMENTS

A production method of a gas barrier film of the present invention is a method including the steps of: forming a smoothing layer on one surface of a resin substrate; and forming a gas barrier layer containing a carbon atom, a silicon atom and an oxygen atom on a surface of the smoothing layer. It is characterized that a surface of the smoothing layer has a specific surface free energy, and that the gas barrier layer is formed employing a raw material gas containing an organic silicon compound and an oxygen gas with a specific discharge plasma chemical vapor deposition method. By the aforesaid embodiment, the present invention provides a production method of a gas barrier film having a gas barrier property required for an electronic device application under the using condition of high temperature and high humidity such as an outdoor usage, as well as having high flexibility and excellent adhesion property. This feature is a technical feature commonly owned by the inventions according to claims 1 to 7.

In addition, the aforesaid “a discharge plasma chemical vapor deposition method having a discharge space between rollers applied with a magnetic field” is simply called as “a roller space discharge plasma chemical vapor deposition method impressed with a magnetic field to the rollers, or “a roller space discharge plasma chemical vapor deposition method” in the present application.

As embodiments of the present invention, the following are preferable from the viewpoint of expression effect of the present invention:

(1) a carbon atomic ratio of the gas barrier layer is continuously changed in a thickness direction in relation to a distance from a surface of the gas barrier layer within a distance range of 89% from the surface of the gas barrier layer when a thickness of the gas barrier layer in a vertical direction is set to be 100%;
(2) a maximum value of the carbon atomic ratio of the gas barrier layer in the thickness direction is less than 20 at % within the distance range of 89% from the surface of the gas barrier layer when the thickness of the gas barrier layer in a vertical direction is set to be 100%;
(3) a carbon atomic ratio of the gas barrier layer is continuously increased in the thickness direction within the distance range of 90 to 95% from the surface of the gas barrier layer when the thickness of the gas barrier layer in a vertical direction is set to be 100%; and
(4) a maximum value of the carbon atomic ratio of the gas barrier layer in the thickness direction is 20 at % or more within the distance range of 90 to 95% from the surface of the gas barrier layer when the thickness of the gas barrier layer in a vertical direction is set to be 100%.

These are preferable embodiments to obtain a gas barrier film having a superior flexibility and excellent adhesion property. Further, it is preferable that the aforesaid smoothing layer is formed by coating a composition containing a resin having a radical reactive unsaturated bond, an inorganic particle, a photo-initiator, a solvent, and a reactive diluting agent; and a ratio of the reactive diluting agent is in the range of 0.1 to 10 mass % in order to precisely control the carbon content under a required condition.

In order achieve higher gas barrier property, the following embodiment is preferable. On the aforesaid gas barrier layer, a second gas barrier layer is formed by coating a polysilazane containing liquid on the gas barrier film, followed by drying to form a coated film, then, the coated film is subjected to a reforming treatment by irradiating with vacuum ultraviolet rays having a wavelength of 200 nm or less. By this method, it can bury the minute defects remaining in the gas barrier layer formed with a plasma CVD method with a gas barrier component of polysilazane from the upper part. Further, by making an electronic device provided with a gas barrier film of the present invention, it can achieve an electronic device having an extremely superior gas barrier property, flexibility and adhesion property even under the using condition of high temperature and high humidity such as an outdoor usage′.

In addition, “the gas barrier property” of the present invention means that it has: a water vapor permeability of 3×10⁻³ g/(m²·24 h) or less (temperature: 60±0.5° C., relative humidity: 90±2% RH) determined based on JIS K 7129-1992; and an oxygen permeability of 1×10⁻³ ml/(m²·24 h·atm) or less, determined based on JIS K 7126-1987.

In addition, in the present invention, “vacuum ultraviolet ray”, “vacuum ultraviolet light”, “VUV” and “VUV light” indicates a light having a wavelength of 100 to 200 nm.

The present invention and the constitution elements thereof, as well as configurations and embodiments to perform the present invention, will be detailed in the following. In the present application, when two figures are used to indicate a range of value before and after “to”, these figures are included in the range as a lowest limit value and an upper limit value.

### <<Summary of a Production Method of a Gas Barrier Film of the Present Invention>>

A production method of a gas barrier film of the present invention is a method including the steps of: forming a smoothing layer on one surface of a resin substrate; and forming a gas barrier layer containing a carbon atom, a silicon atom and an oxygen atom on a surface of the smoothing layer. It is characterized that a surface of the smoothing layer is controlled to have a dispersion component of a surface free energy in the range of 30 to 40 mN/m at an environment of 23° C. and 50% RH; and the gas barrier layer is formed employing a raw material gas containing an organic silicon compound and an oxygen gas with a discharge plasma chemical vapor deposition method having a discharge space between rollers applied with a magnetic field.

In the following, a smoothing layer having a feature of the present invention, a production method of a gas barrier layer, and a content of composition of the layer will be described one by one.

### <<Basic Composition of a Gas Barrier Film>>

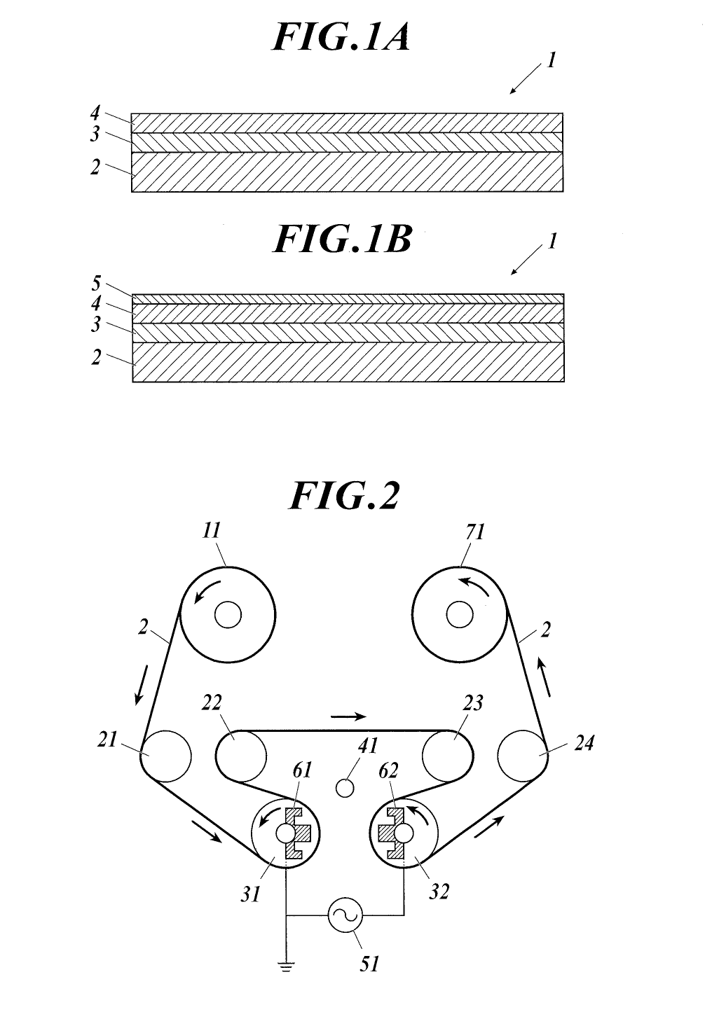

FIG. 1 is a schematic cross sectional drawing showing an example of a basic composition of a gas barrier film of the present invention.

As shown in FIG. 1, a gas barrier film 1 of the present invention has a resin substrate 2 as a support, and a smoothing layer 3 on one surface of the resin substrate 2. It has a gas barrier layer 4 formed with a roller space discharge plasma chemical vapor deposition method on the surface of the resin substrate 2 having the smoothing layer 3 (FIG. 1A). Further, a second gas barrier layer 5, which is formed with polysilazane coated layer treated by irradiation with vacuum ultraviolet rays (VUV), is provided on the gas barrier layer 4 according to necessity (FIG. 1B).

### [1] Smoothing Layer

In the gas barrier film of the present invention, on a surface of the resin substrate to which is provided with a gas barrier layer of the present invention, it is formed a smoothing layer having a dispersion component of a surface free energy in the range of 30 to 40 mN/m at an environment of 23° C. and 50% RH. In particular, by controlling the dispersion component of a surface free energy to be in the range of 33 to 38 mN/m, the adhesion property and the gas barrier property will be improved. This is a preferable embodiment.

A smoothing layer having the aforesaid dispersion component of a surface free energy is formed on the surface which is provided with a gas barrier layer. The gas barrier layer is formed with a roller space discharge plasma chemical vapor deposition method impressed with a magnetic field to the rollers. By this method, it can orient a carbon atom component to the neighbor portion of the resin substrate. As a result, the adhesion property of the resin substrate with the gas barrier layer is improved and the gas barrier property is also improved.

When the dispersion component of a surface free energy of the smoothing layer is within the range of 30 to 40 mN/m, it can obtain a surface having an appropriate wetting property with a gas barrier layer formed with a roller space discharge plasma chemical vapor deposition method. Consequently, it can control the carbon atom component in the neighbor portion of the resin substrate to a predetermined condition. As a result, a excellent adhesion property and gas barrier property can be realized. On the other hand, when the dispersion component of a surface free energy is less than 30 mN/m, or more than 40 mN/m, the amount of the carbon atom component in the neighbor portion of the resin substrate becomes small. As a result, the adhesion property and the barrier property are deteriorated.

A dispersion component γSD of a surface free energy of the present invention is measured with the following method.

A contact angle of the produced smoothing layer surface with a standard liquid (mixture of three solvents: water, nitromethane and diiodomethane) is measured with an automatic contact angle measuring apparatus CA-V (made by Kyowa Interface Science, Co. Ltd.). A γSH value is calculated based on the following scheme. A dispersion component γSD, and a hydrogen bond component γSH (mN/m)

of a surface free energy are determined. Here, it was used a contact angle measured by dropping 3 μl of solvent on the smoothing layer under the environment of 23° C. and 50% RH, and the measurement was done 100 msec after reaching the liquid to the surface.

γL·(1+cos θ)/2=(γSD·γLD)^{1/2}+(γSP·γLP)^{1/2}+(γSH·γLH)^{1/2}

In the scheme:

γL: Surface tension of liquid

θ: Contact angle of liquid with solid

γSD, γSP and γSH: Dispersion, polar, hydrogen bond component of surface free energy of solid

γLD, γLP and γLH: Dispersion, polar, hydrogen bond component of surface free energy of liquid

γL=γLD+γLP+γLH

γS=γSD+γSP+γSH

In addition, as three components (γSD, γSP and γSH) of surface free energy of standard liquids, by using the following values, and by solving 3 simultaneous equation based on each contact angle value, each component value (γSD, γSP and γSH) of the surface free energy of the solid was determined.

[Water (29.1, 1.3, 42.4); Nitromethane (18.3, 17.7, 0); and Diiodomethane (46.8, 4.0, 0)]

The measurement of surface free energy can be done with a sample having been formed with a gas barrier layer on the smoothing layer of the present invention by peeling off the aforesaid gas barrier layer with a means such as dry etching. For example, after peeling off the gas barrier layer on the surface of the gas barrier film in an area of 1 cm×1 cm with an etching method, a surface free energy can be measured in the same way as described above. As a specific peeling off method, or apparatus, it can use a dry etching apparatus E600L or E620 (made by Panasonic, Co. Ltd.). By using the aforesaid measuring method in the peeled off area, it can confirm whether the smoothing layer has a surface free energy in the range of the present invention or not.

The composition of the smoothing layer according to the present invention is not specifically limited as long as it is provided with a surface free energy. It is preferable that it is formed by coating a composition containing a resin having a radical reactive unsaturated bond, an inorganic particle, a photo-initiator, a solvent, and a reactive diluting agent. Further, it is preferable that the content ratio of the reactive diluting agent in the smoothing layer is in the range of 0.1 to 10 mass %. In the aforesaid smoothing layer, the required surface free energy can be adjusted by suitably controlling: the composition ratio of a resin having a radical reactive unsaturated bond, an inorganic particle, a photo-initiator, a solvent, and a reactive diluting agent; and the structure or the size of the composing material.

In particular, the adjustment of the surface free energy is controlled mainly by the kind of the resin having a radical reactive unsaturated bond, and by the kind and the amount of the reactive diluting agent.

### <1.1> Resin Having a Radical Reactive Unsaturated Bond

Examples of a resin applicable to the smoothing layer according to the present invention include: an epoxy resin, an acrylic resin, an urethane resin, a polyester resin, a silicon resin, and an ethylene vinyl acetate (EVA) resin. By employing these resins, optical transparency of the resin composition can be increased. Particularly, among the aforesaid resins, a resin having a radical reactive unsaturated bond of a photo curing type or a thermal curing type is preferably used. Specifically, a UV curable resin is preferable from the viewpoint of productivity, hardness, smoothness, and transparency of the produced film.

As a UV curable resin, it can use a resin which is cured by irradiation with Ultraviolet rays and to produce a transparent resin composition without specific limitation. Particularly preferable are an acrylic resin, an urethane resin, and a polyester resin from the viewpoint of hardness, smoothness, and transparency of the produced smoothing layer.

Examples of an acrylic resin composition include a composition dissolving a polyfunctional acrylate monomer such as: an acrylate compound having a radical reactive unsaturated bond, an acrylate compound with a mercapto compound having a thiol group, an epoxy acrylate, urethane acrylate, polyester acrylate, polyether acrylate, polyethylene glycol acrylate, and glycerol methacrylate. Further, it is possible to use a mixture obtained by mixing the aforesaid resin composition with any mixing ratio. The resin is not limited as long as it contains a reactive monomer having one or more photo curable unsaturated bond in the molecule.

Preferable specific examples are: UV curable resin UNIDIC V-4025 (made by DIC Co. Ltd.), and LCH1559 (Silica containing hybrid hard coating agent: made by Toyochem Co., Ltd.). However, the present invention is not limited to them. Among them, the most preferable is LCH1599 which contains an inorganic particle. As a photo-initiator, it can use a known compound such as Irgacure 184 (made by BASF Japan, Co. Ltd.). It can use one, or it can use by combining two or more kinds.

### <1.2> Reactive Diluting Agent

A reactive diluting agent according to the present invention is a mono functional reactive monomer containing one acryl group or methacryl group per one molecule. Originally, it has a role to decrease the viscosity of an oligomer having a high viscosity value. However, in the present invention, it has also has a role to adjust a dispersing component of a surface free energy.

Since a reactive diluting agent according to the present invention has a role to adjust a dispersing component of a surface free energy, it is preferable that it contains a polar group or a hydrophobic group. Examples of a hydrophobic group are: an epoxy group, an ethylene oxide group, a carbonyl group, a hydroxy group, a carboxy group, a phosphate group, and a primary, a secondary and a tertiaryl amino group. Examples of a hydrophobic group are: a methylene group, an isobornyl group and a pentenyl group. By combining two types of structures, and by adjusting the added amount, it can appropriately adjust the surface free energy.

The added amount of the reactive diluting agent according to the present invention is preferably in the range of 0.1 to 10 mass % with respect to the mass of the smoothing layer in view of the dispersion component of the surface free energy, and formation and surface hardness of the cured coating film. More preferably, it is in the range of 1 to 5 mass %.

When it is in the range of 0.1 to 10 mass %, an appropriate dispersion component of the surface free energy can be obtained. It can obtain a sufficient adhesion property with the gas barrier layer and a sufficient gas barrier property. This is preferable. In addition to that, it can obtain a sufficient smoothness and a sufficient hardness. This will avoid generation of scratch during contact with roller when a roller space discharge plasma chemical vapor deposition method is performed.

Preferable examples of a reactive diluting agent include: Surflon S-651 (fluoro-oligomer: made by AGC Seimi Chemical, Co. Ltd.), hydroxyethyl methacrylate, FA-512M (dicyclopentenyl oxyethyl methacrylate: made by Hitachi Chemical, Co. Ltd.), phosphoric acid acrylate: Light acrylate P-1A (made by Kyoeisha Chemical, Co. Ltd.), GMA (Light ester G glycidyl methacrylate (made by Kyoeisha Chemical, Co. Ltd.), and isobornyl methacrylate: Light ester IB-X (made by Kyoeisha Chemical, Co. Ltd.). However, the present invention is not limited to them.

### <1.3> Inorganic Particle

Examples of an inorganic particle include: a silica particle such as dry silica or wet silica; a metal oxide particle such as titanium oxide, zirconium oxide, zinc oxide, tin oxide, cerium oxide, antimony oxide, indium-tin mixed oxide and antimony tin mixed oxide; an organic particle such as acryl and styrene. In particular, it is preferable to use a nano-dispersion silica particle dispersed silica particles having a size in the range of 10 to 50 nm from the view point of transparency and hardness.

Further, it is preferable that the inorganic particle is contained in an amount of 5 to 50 mass parts with respect to 100 mass parts of the curable resin which composes the smoothing layer. In particular, is it preferable that it is contained in an amount of 10 to 40 mass parts. The added amount will be suitably determined by an arithmetic average roughness describe later.

### <1.4> Formation Method of a Smoothing Layer

A smoothing layer according to the present invention is formed by coating a composition (smoothing layer forming liquid) containing a resin having a radical reactive unsaturated bond as described above, an inorganic particle, a photo-initiator, a solvent, and a reactive diluting agent. Examples of a coating method are: a doctor blade method, a spin coating method, a dipping method, a table coating method, a spraying method, an applicator method, a curtain coating method, a die coating method, an inkjet method, and a dispenser method. Then, after adding a curing agent when required, the resin composition is cured with applying heating or irradiating with ultraviolet rays.

As a method of curing a UV curable resin by irradiating with ultraviolet rays, it can use an ultra-high pressure mercury lamp, a high pressure mercury lamp, a low pressure mercury lamp, a carbon arc, or a metal halide lamp. The ultraviolet rays in the range of 100 to 400 nm, more preferably, in the range of 200 to 400 nm emitted from these light sources are irradiated. Otherwise, it can be done by irradiating with an electron beam having a wavelength of 100 nm or less emitted from a scanning type or a curtain type electron beam accelerator.

Although the thickness of the smoothing layer of the present invention is not specifically limited, it is preferably, in the range of 0.1 to 10 μm, and more preferably, in the range of 0.5 to 5 μm. The smoothing layer may have a composition of two or more layers.

The smoothing layer of the present invention may further contain additives such as an antioxidant, a plasticizer, other matting agent, and a thermoplastic resin when needed. When a solvent is used for a smoothing layer forming coating liquid to dissolve or to disperse a resin, the solvent is not specifically limited. It can use known organic solvents by suitably selecting from known alcohol solvents, aromatic hydrocarbon solvents, ether solvents, ketone solvents and ester solvents. Among these, MEK (methyl ethyl ketone) can be suitably used.

### <1.5> Arithmetic Average Surface Roughness Ra of the Smoothing Layer

The smoothing layer according to the present invention is preferable to have an arithmetic average surface roughness Ra in the range of 0.5 to 2.0 nm, and more preferably, in the range of 0.8 to 1.5 nm.

When the smoothing layer has an arithmetic average surface roughness Ra in the range of 0.5 to 2.0 nm, the surface of the smoothing layer has a suitable roughness. As a result, a roller conveying property during gas barrier layer formation is stabilized by the friction property with the roller. It can precisely perform formation of gas barrier layer with a roller space discharge plasma chemical vapor deposition method, and it enables to form a uniform gas barrier layer.

An arithmetic average surface roughness Ra of the smoothing layer according to the present invention can be measured with the following method.

### <Measuring Method of Arithmetic Average Surface Roughness Ra: AFM Measurement>

The surface roughness is a roughness relating to an amplitude of minute irregularity measured by using an atomic force microscope (AFM), for example, DI3100 made by Digital Instruments, Co. Ltd. This surface roughness is obtained by multiple measurements within a range of several tens μm using a stylus of the minimal tip radius. It is calculated from a cross-section curve of the irregularity obtained by this continuous measurement.

### [2] Gas Barrier Layer

The gas barrier layer according to the present invention is characterized in: being formed on a surface of a smoothing layer by using a deposition gas containing a raw material gas including an organic silicon compound and an oxygen gas with a roller space discharge plasma chemical vapor deposition method by impressing a magnetic field to the rollers; and containing a carbon atom, a silicon atom and an oxygen atom as constituting elements of the gas barrier layer.

Specifically, the gas barrier layer is formed on the resin substrate with a plasma chemical vapor deposition method. That is, a resin substrate is conveyed with the surface of the resin substrate opposite to the other surface having a smoothing layer being in contact with a pair of deposition rollers (roller electrodes). Then, plasma is discharged between the deposition rollers by impressing a magnetic field to the rollers while supplying a deposition gas.

The gas barrier layer according to the present invention is formed with a deposition gas containing a raw material gas including an organic silicon compound and an oxygen gas. It contains carbon atom, a silicon atom, and an oxygen atom as constituting elements. A more preferable embodiment is to satisfy all of the following conditions (1) to (4) for the carbon atomic distribution profile.

(1) The carbon atomic ratio of the gas barrier layer continuously changes in a thickness direction in relation to a distance from a surface of the gas barrier layer within a distance range of 89% from the surface of the gas barrier layer when a thickness of the gas barrier layer in a vertical direction is set to be 100%.
(2) A maximum value of the carbon atomic ratio of the gas barrier layer in the thickness direction is less than 20 at % within the distance range of 89% from the surface of the gas barrier layer when the thickness of the gas barrier layer in a vertical direction is set to be 100%.
(3) A carbon atomic ratio of the gas barrier layer is continuously increased in the thickness direction within the distance range of 90 to 95% from the surface of the gas barrier layer when the thickness of the gas barrier layer in a vertical direction is set to be 100%.
(4) A maximum value of the carbon atomic ratio of the gas barrier layer in the thickness direction is 20 at % or more within the distance range of 90 to 95% from the surface of the gas barrier layer when the thickness of the gas barrier layer in a vertical direction is set to be 100%.

In the present invention, an average value of the content ratio of the carbon atoms and a carbon atomic distribution in the gas barrier layer of the present invention can be determined by the measurement of XPS depth profile.

The detail of the gas barrier layer according to the present invention will be further described in the following.

### <2.1> Carbon Atom Profile in the Gas Barrier Layer

The gas barrier layer of the present invention contains a carbon atom, a silicon atom and an oxygen atom as constituting elements. The carbon distribution curve indicates the relationship between the distance from the surface in the thickness direction of the gas barrier layer and the ratio of the amount of the carbon atoms (carbon atomic ratio) with respect to the total amount of silicon atoms, oxygen atoms and carbon atoms. In this carbon distribution curve, it is preferable that the carbon atom content profile will satisfy all of the above-described conditions (1) to (4) from the viewpoint of obtaining a gas barrier film excellent in flexibility and adhesion property.

In addition, a preferable embodiment is one having a composition in which a carbon atomic ratio in a specific region of the gas barrier layer changes continuously, from the viewpoint of achieving both gas barrier property and flexibility.

In the gas barrier layer of the present invention having the carbon atomic distribution profile as described above, it is preferable that carbon atomic distribution curve in the layer has at least one extreme value. Further, it is more preferable that it has at least two extreme values, and it is still more preferable that it has at least three extreme values. When the aforesaid carbon atomic distribution curve has the extreme value, the gas barrier property of the produced gas barrier film after bending is improved. This is favorable. When it has at least two or three extreme values, it is preferable that the absolute value of the difference of the distance from the surface in the thickness direction of one extreme value point and the adjacent extreme value point is 200 nm or less, and more preferably, it is 100 nm or less.

In the present invention, an extreme value indicates a local maximum value or a local minimum value of each element.

### (2.1.1) Local Maximum Value and Local Minimum Value

The local maximum value in the present invention represents a point at which the atomic ratio of the element changes from an increase to a decrease when the distance from the surface of the gas barrier layer varies, and from which point the atomic ratio of the element decreases by 3 at % or more when the distance from the surface of the gas barrier layer in the thickness direction varies by 20 nm.

The local minimum value in the present invention represents a point at which the atomic ratio of the element changes from a decrease to an increase when the distance from the surface of the gas barrier layer varies, and from which point the atomic ratio of the element increases by 3 at % or more when the distance from the surface of the gas barrier layer in the thickness direction varies by 20 nm.

Preferable embodiments of the gas barrier layer according to the present invention are: (1) a maximum value of the carbon atomic ratio of the gas barrier layer is less than 20 at % within the distance range of 89% when the thickness of the gas barrier layer in a vertical direction from a surface of the gas barrier layer (from a surface opposite to a surface contacting the resin substrate) is set to be 100%; and (3) a maximum value of the carbon atomic ratio of the gas barrier layer is 20 at % or more within the distance range of 90 to 95% when the thickness of the gas barrier layer in a vertical direction from a surface of the gas barrier layer is set to be 100%.

### (2.1.1) Continuous Change of Density Gradient

In the present invention, preferable embodiments of the gas barrier layer are: (2) a carbon atomic ratio of the gas barrier layer has a density gradient and it is continuously changed in a thickness direction within a distance range of 89% when the thickness of the gas barrier layer in a vertical direction from the surface of the gas barrier layer is set to be 100%; and (4) a carbon atomic ratio of the gas barrier layer in the thickness direction is continuously increased within the distance range of 90 to 95% when the thickness of the gas barrier layer in a vertical direction from the surface of the gas barrier layer is set to be 100%.

In the present invention, “the density gradient of the carbon atomic ratio changes continuously” means that the carbon atomic ratio in the carbon distribution curve does not include any potions of discontinuity. Specifically, it means that the condition represented by the following mathematical expression (F1) is satisfied, F1 being the relationship between the distance x (in nm) from the surface of the gas barrier layer of the present invention in the thickness direction, which is derived from the etching rate and the etching time, and the carbon atomic ratio (C in at %):

(dC/dx)≦0.5 Expression (F1):

### (2.2) Each Element Profile in the Gas Barrier Layer

The gas barrier layer of the present invention is characterized in containing a carbon atom, a silicon atom, and an oxygen atom as constituting elements. Preferable embodiments of atomic ratio, maximum value and minimum value of each element will be described in the following.

### (2.2.1) Relationship Between Maximum Value and Minimum Value of Carbon Atomic Ratio

In the gas barrier layer according to the present invention, it is preferable that an absolute value of the difference between the maximum value and the minimum value of the carbon atomic ratio in the carbon distribution curve is 5 at % or more. In this gas barrier layer, it is more preferable that an absolute value of the difference between the maximum value and the minimum value of the carbon atomic ratio is 6 at % or more. And still more preferably, it is 7 at % or more. By making an absolute value of the difference between the maximum value and the minimum value of the carbon atomic ratio to be 5 at % or more, the gas barrier property of the produced gas barrier film after bending is improved. This is favorable.

### (2.2.2) Relationship Between Maximum Value and Minimum Value of Oxygen Atomic Ratio

In the gas barrier layer according to the present invention, it is preferable that an absolute value of the difference between the maximum value and the minimum value in the oxygen distribution curve is 5 at % or more. More preferably, it is 6 at % or more. And still more preferably, it is 7 at % or more. When the aforesaid absolute value is 5 at % or more, the gas barrier property of the produced gas barrier film after bending is improved. This is favorable.

### (2.2.3) Relationship Between Maximum Value and Minimum Value of Silicon Atomic Ratio

In the gas barrier layer according to the present invention, it is preferable that an absolute value of the difference between the maximum value and the minimum value in the silicon distribution curve is less than 5 at %. More preferably, it is less than 4 at %. Still more preferably, it is less than 3 at %. When the aforesaid absolute value is less than 5 at %, the gas barrier property and mechanical strength of the produced gas barrier film is improved. This is favorable.

### (2.2.4) Ratio of the Total Amount of Oxygen Atoms and Carbon Atoms

In the gas barrier layer according to the present invention, the relation between the distance from the surface of the said layer in the thickness direction and the ratio of the total amount of oxygen atoms and carbon atoms with respect to the total amount of silicon atoms, oxygen atoms and carbon atoms (it is called as an atomic ratio of the sum of oxygen-carbon) is shown in the distribution curve of the sum of oxygen-carbon (it is called as an oxygen-carbon distribution curve). In this distribution curve, it is preferable that the absolute value of the difference between the maximum value and the minimum value of the atomic ratio of the sum of oxygen-carbon is less than 5 at %, more preferably, less than 4 at %, and particularly preferably, less than 3 at %. When it is less than 5 at %, the gas barrier properties of the obtained gas barrier film is improved. This is favorable.

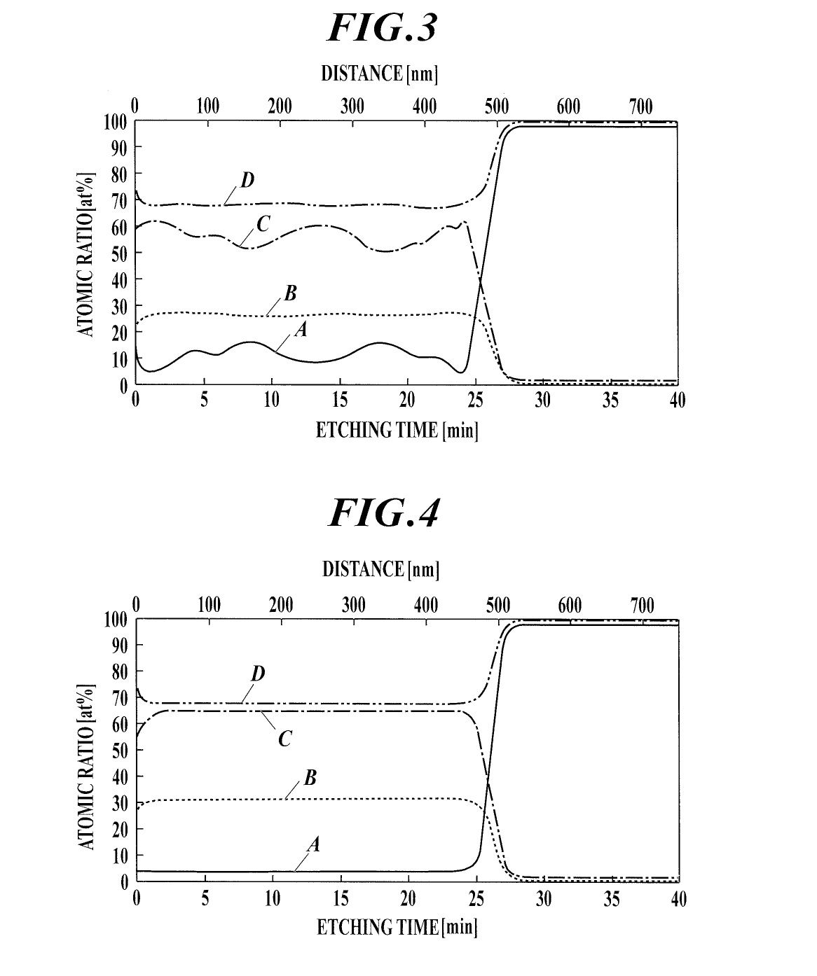

In the above-described description of the carbon atomic distribution profile (silicon distribution curve, oxygen distribution curve, and carbon distribution curve) as illustrated in FIG. 3 and FIG. 4, “the total amount of silicon atoms, oxygen atoms and carbon atoms” means a total atomic number of silicon atoms, oxygen atoms and carbon atoms. “An amount of carbon atoms” means a carbon atomic number. In the present invention, at % indicates an atomic number ratio of each element when the total atomic number of silicon atoms, oxygen atoms and carbon atoms is set to be 100 at %. In the same way, “an amount of silicon atoms” and “an amount of oxygen atoms” in a silicon distribution curve and an oxygen distribution curve as illustrated in FIG. 3 and FIG. 4 are described.

### <2.3> Elemental Composition Component Analysis (XPS Depth Profiling)

A silicon distribution curve, an oxygen distribution curve, a carbon distribution curve, and an oxygen-carbon distribution curve of the gas barrier layer in the thickness direction will be prepared through so-called XPS depth profiling in which the interior of the specimen is exposed in sequence for analysis of the surface composition component analysis through a combination of X-ray photoelectron spectroscopy (XPS) and ion-beam sputtering using a rare gas, such as argon.

Each distribution curve acquired through such XPS depth profiling has, for example, a vertical axis representing an atomic ratio (unit: at %) of the element and a horizontal axis representing an etching time (sputtering time). In a distribution curve of an element having an etching time as a horizontal axis, the etching time correlates approximately with the distance from the surface of the aforesaid gas barrier layer in the thickness direction of the gas barrier layer. Thus, a distance from the surface of the gas barrier layer calculated on the basis of the relationship between the etching rate and etching time used in the XPS depth profiling may be adopted was a distance from the surface of the gas barrier layer in the thickness direction”.

For the XPS depth profiling, it is preferable to select an ion-beam sputtering of a rare gas using argon (Ar⁺) as an etching ionic species and an etching rate of 0.05 nm/sec (equivalent to a value for a thermally-oxidized SiO₂ film).

In the present invention, from the viewpoint of forming a gas barrier layer having a uniform layer and superior gas barrier property, it is preferable that the gas barrier layer is substantially uniform in the layer surface direction (the direction parallel to the surface of the gas barrier layer). In this specification, a gas barrier layer being substantially uniform in the film surface direction means the following. When the aforesaid oxygen distribution curve, the aforesaid carbon distribution curve, and the aforesaid oxygen-carbon distribution curve are prepared at any two points of the gas barrier layer thorough measurement of XPS depth profiling, the element distribution curves for the two points contain the same number of extremum points, and the absolute values of the differences between the maximum value and the minimum value of the carbon atomic ration in the carbon distribution curves are identical or have a difference of 5 at % or less.

It is preferable that the gas barrier film of the present invention is provided with at least one gas barrier layer satisfying all of the aforesaid conditions of (1) to (4). It may be provided with two or more layers satisfying such conditions. When the two or more gas barrier layers as described above are provided, the material for the plural gas barrier layers may be the same or different. Further, when the two or more gas barrier layers as described above are provided, such gas barrier layers may be formed on one surface of the aforesaid substrate, or may by formed on both surfaces of the aforesaid substrate. In addition, as the plural gas barrier layers, it may contain a gas barrier layer without a gas barrier property.

In the aforesaid silicon distribution curve, oxygen distribution curve, and carbon distribution curve, the silicon atomic ratio, the oxygen atomic ratio, and the carbon atomic ratio preferably show the following property within the distance range of 89% of the thickness from the surface of the barrier layer. It is preferable that a maximum value of the silicon atomic ratio with respect to the sum of silicon atoms, oxygen atoms and carbon atoms is in the range of 19 to 40 at %. More preferably, it is in the range of 25 to 35 at %. In addition, a maximum value of the oxygen atomic ratio with respect to the sum of silicon atoms, oxygen atoms and carbon atoms is in the range of 33 to 67 at %. More preferably, it is in the range of 41 to 62 at %. Further, a maximum value of the carbon atomic ratio with respect to the sum of silicon atoms, oxygen atoms and carbon atoms is in the range of 1 to 19 at %. More preferably, it is in the range of 3 to 19 at %.

### <2.4> Thickness of Gas Barrier Layer

A thickness of the gas barrier layer of the present invention is preferably in the range of 5 to 3,000 nm, more preferably in the range of 10 to 2,000 nm, and still more preferably in the range of 100 to 1,000 nm. When the gas barrier layer has a thickness within these ranges, the gas barrier layer has sufficient gas barrier properties such as oxygen gas barrier property and water vapor barrier property. In addition, the gas barrier property will not be easily decreased after bending of the gas barrier layer. This is preferable.

When the gas barrier film of the present invention includes a plurality of gas barrier layers, the total thickness of the gas barrier layers is normally in the range of 10 to 10,000 nm, preferably in the range of 10 to 5,000 nm, more preferably in the range of 100 to 3,000 nm. Further, the range of 200 to 2,000 nm is particularly preferable. When the gas barrier layers have a total thickness within these ranges, the gas barrier layers have sufficient gas barrier properties such as oxygen gas barrier property and water vapor barrier property. In addition, the gas barrier property will not be easily decreased after bending of the gas barrier layer.

### <2.5> Formation Method of Gas Barrier Layer

The gas barrier layer according to the present invention is characterized in being formed with a roller space discharge plasma chemical vapor deposition method by impressing a magnetic field to the rollers.

More specifically, the gas barrier layer according to the present invention is formed with a plasma chemical vapor deposition method. Namely, by employing a roller space discharge plasma treatment apparatus by impressing a magnetic field to the rollers, a resin substrate is conveyed in contact with a pair of deposition rollers, and plasma is discharged between the deposition rollers by impressing a magnetic field to the rollers while supplying a deposition gas. During discharge between the pair of deposition rollers by impressing a magnetic field to the rollers, it is preferable that the polarities of the deposition rollers are alternately inverted. Further, the deposition gas used in the aforesaid plasma chemical vapor deposition method preferably includes a raw material gas containing an organosilicon compound and an oxygen gas. The content of the oxygen gas in the deposition gas is preferably equal to or less than a theoretical quantity required for the complete oxidation of the entire quantity of the organosilicon compound in the deposition gas. The gas barrier layer of the present invention is preferably a layer formed through a continuous deposition process.

That is, the gas barrier film of the present invention is formed by forming a gas barrier layer on the smoothing layer formed on the resin substrate with a roller space discharge plasma treatment apparatus by impressing a magnetic field to the rollers.

In the gas barrier layer according to the present invention, the formed layer has a carbon atomic ratio with a density gradient and the carbon atomic ratio changes continuously in the layer. Therefore, it has a feature of using a roller space discharge plasma chemical vapor deposition method by impressing a magnetic field to the rollers.

In the roller space discharge plasma chemical vapor deposition method by impressing a magnetic field to the rollers of the present invention (hereafter, it is simply called as a roller CVD method), it is preferable to produce plasma discharge in the formed discharge space by impressing a magnetic field to the plural deposition rollers when producing plasma. In the present invention, the following is a preferable embodiment. It is used a pair of deposition rollers, and a resin substrate is conveyed in contact with each of the pair of deposition rollers, and plasma is discharged between the pair of the deposition rollers by impressing a magnetic field. As described above: it is used a pair of deposition rollers; a resin substrate is conveyed in contact with the pair of deposition rollers; and plasma is discharged between the pair of the deposition rollers. By this method, the distance between the resin substrate and the deposition rollers will change. As a result, it is possible to form a gas barrier layer in which the aforesaid carbon atomic ratio has a density gradient and the carbon atomic ratio changes continuously in the layer.

In addition, while forming a layer on the surface portion of the resin substrate existing on one deposition roller, at the same time, it can form a layer on the surface portion of the resin substrate existing on the other deposition roller. Thus, it can effectively produce a thin film and the deposition rate will be increased to double. In addition, it may form a layer having the same composition. As a result, it can increase the number of extreme values in the aforesaid carbon distribution curve at least to double. Consequently, it can effectively form a layer satisfying the above-described conditions (1) to (4).

A gas barrier film of the present invention is preferably produced by forming the aforesaid gas barrier layer on a surface of the aforesaid substrate through a roll-to-roll processing in view of productivity.

Although any apparatus may be used for the production of the gas barrier film through a plasma chemical vapor deposition method, the apparatus preferably includes at least a pair of deposition rollers provided with an apparatus to impress a magnetic field and a plasma power source, and is capable of discharging in the space between the deposition rollers. For example, the manufacturing apparatus illustrated in FIG. 2 can produce a gas barrier film through a plasma chemical vapor deposition method in a roll-to-roll process.

With reference to FIG. 2, a method for manufacturing a gas barrier film of the present invention will now be described in detail. FIG. 2 is a schematic drawing showing an example of a roller space discharge plasma CVD apparatus by impressing a magnetic field to the rollers, which is preferably used for producing a gas barrier film of the present invention. A resin substrate 2, which is described in the following, is a resin substrate provided with a smoothing layer on the rear side.

The roller space discharge plasma CVD apparatus (hereafter, it is also simply called as a roller CVD apparatus) illustrated in FIG. 2 includes mainly a delivery roller 11, conveyer rollers 21, 22, 23 and 24, deposition rollers 31 and 32, a deposition gas inlet 41, a power source 51 for plasma generation, magnetic-field generators 61 and 62 disposed inside the deposition rollers 31 and 32, and a reeling roller 71. Such a roller CVD apparatus includes a vacuum chamber (not shown) that accommodates at least the deposition rollers 31 and 32, the deposition gas inlet 41, the power source 51 for plasma generation, and the magnetic-field generators 61 and 62. The vacuum chamber of such a roller CVD apparatus is connected to a vacuum pump (not shown). The vacuum pump can appropriately adjust the pressure in the vacuum chamber.

In the aforesaid roller CVD apparatus, a pair of deposition rollers (deposition rollers 31 and 32) are connected to the power source 51 for plasma generation so that the deposition rollers can function as opposing electrodes. Thus, electric power will be supplied from the power source 51 for plasma generation to the pair of deposition rollers (deposition rollers 31 and 32) and discharge will be done in the space between the deposition rollers 31 and 32. This will generate plasma in the space between the deposition rollers 31 and 32. The deposition rollers 31 and 32 may be used as electrodes by appropriately selecting the material and design for the deposition rollers suitable as electrodes. The deposition rollers (deposition rollers 31 and 32) in the roller CVD are preferably disposed such that the central axes of the rollers 31 and 32 are substantially parallel to each other on a single plane. Such arrangement of the deposition rollers (deposition rollers 31 and 32) will make double the deposition rate and it will deposit a film with an identical structure. As a result, the number of extreme value points in the aforesaid carbon distribution curve may be increased at least to double.

The deposition rollers 31 and 32 respectively accommodate the magnetic-field generators 61 and 62, which are fixed without rotation even when the deposition rollers rotate. Commonly permanent magnets are preferably used for the magnetic-field generators.

The magnetic-field generators 61 and 62 attached to the deposition rollers 31 and 32 are preferably arranged to have the magnetic pole in the following. The magnetic lines are not crossed between the magnetic-field generator 61 attached to the one deposition roller 31 and the magnetic-field generator 62 attached to the other deposition roller 32. The magnetic-field generators 61 and 62 each respectively form a closed magnetic circuit. By placing the magnetic-field generators 61 and 62, it can promote a formation of the magnetic-field having magnetic lines which swell to the opposite side of the deposition rollers 31 and 32. Plasma is easily focused on the swelling portion. As a result, this method is superior in the point of increasing the deposition efficiency.

The magnetic-field generators 61 and 62 attached to the deposition rollers 31 and 32 each have a race truck shape magnetic pole elongated in the roller axis direction. It is preferable that one magnetic-field generator 61 and the other magnetic-field generator 62 are arranged in such a manner that the opposing magnetic poles have the same polar character. By placing such magnetic-field generators 61 and 62, the magnetic lines of the magnetic-field generators 61 and 62 will not cross over the magnetic-field generator of the opposing roller side. Thus, it can easily form a race truck shape magnetic field near the roller surface facing the opposing space (discharge region) elongated in the roller axis direction. Plasma can be focused to the formed magnetic-filed. An inorganic gas barrier layer 4 made of vapor deposition film can be efficiently formed using a wide resin substrate 2 which is rolled along eh roller axis. This is an excellent feature.

The deposition rollers 31 and 32 may be any appropriate known roller. The deposition rollers 31 and 32 are preferred to have identical diameters in view of the efficient deposition of the films. The diameter of the deposition rollers 31 and 32 is preferably in the range of 100 to 1,000 mmφ, in particular in the range of 100 to 700 mmφ, in view of the discharge conditions and the space in the chamber. When the diameter is 100 mmφ or more, the plasma discharge space will not be too small. There is no deterioration in productivity. It can avoid the phenomenon that the total amount of heat of the plasma discharge is given in a short time. On the other hand, when the diameter is 1000 mmφ or less, it can maintain the practical condition of the apparatus design, as well as it can achieve uniform plasma discharge space

The delivery roller 11 and the conveyer rollers 21, 22, 23 and 24 of the roller CVD apparatus may be any appropriate known roller. The reeling roller 71 may be any appropriate known roller that can reel the resin substrate 2 on which is formed the gas barrier layer.

The deposition gas inlet 41 may be any appropriate inlet that can supply or discharge a raw material gas at a predetermined rate. The power source 51 for plasma generation may be any appropriate power source for a known plasma generator. The power source 51 for plasma generation supplies power to the deposition rollers 31 and 32 connected thereto and can use the deposition rollers 31 and 32 as opposing electrodes for electrical discharge. The power source 51 for plasma generation is preferably an AC source that will alternatively invert the polarities of the deposition rollers so as to efficiently perform the roller plasma CVD method. The power source 51 for plasma generation is preferred to apply power in the range of 100 W to 10 kW and have an AC frequency in the range of 50 Hz to 500 kHz so as to efficiently perform the roller plasma CVD method. The magnetic-field generators 61 and 62 may be any appropriate known magnetic-field generator.

The roller plasma CVD apparatus, such as that illustrated in FIG. 2, can manufacture the gas barrier film through appropriate adjustment of, for example, the type of raw material gas, the electric power of the electrode drum in the plasma generator, the strength of the magnetic-field generator, the pressure in the vacuum chamber, the diameter of the deposition rollers, and the conveying rate of the resin substrate. That is, the roller plasma CVD apparatus illustrated in FIG. 2 supplies a deposition gas (for example, raw material gas) into the vacuum chamber and generates plasma discharge with impressing the magnetic-field between the deposition rollers (deposition rollers 31 and 32) so as to decompose the deposition gas (for example, raw material gas) by the plasma, and deposit the gas barrier layer on the surface of the resin substrate 2 located on the deposition rollers 31 and 32 through the roller plasma CVD method. Through such deposition process, the resin substrate 2 is conveyed by the delivery roller 11 and the deposition roller 31, and the gas barrier layer is formed on the surface of the resin substrate 2 through continuous roll-to-roll deposition process.

### <2.5.1> Raw Material Gas

A raw material gas composing a deposition gas used for forming a gas barrier layer of the present invention is preferably an organic silicon compound containing silicon.

Examples of an organic silicon compound are:

hexamethyldisiloxane, 1,1,3,3-tetramethyldisiloxane, vinyl trimethylsilane, trimethylsilane, hexamethyldisilane, methylsilane, dimethylsilane, trimethylsilane, diethylsilane, propylsilane, phenylsilane, vinyl triethoxysilanesilane, vinyltrimethoxysilane, tetramethoxysilane, tetraethoxysilane, phenyltrimethoxysilane, methyltriethoxysilane, and octamethylcyclotetrasiloxane. Among these organic silicon compounds, hexamethyldisiloxan and 1,1,3,3-tetramethyldisiloxane are preferably used from the viewpoint of handling during layer formation and light distribution property of the obtained second gas barrier layer. Further, these organic silicon compounds may be used singly, or may be used in combination of two or more.

The aforesaid deposition gas is characterized in containing an oxygen gas as a reactive gas in addition to the raw material gas. An oxygen gas is a gas to form an inorganic compound such as an oxide by reacting with the aforesaid raw material gas.

The aforesaid deposition gas may contain a carrier gas, if required, for supplying the raw material gas to the vacuum chamber. The deposition gas may contain a discharge gas, if required, for the generation of plasma discharge. Such carrier gas and discharge gas may be any appropriate known gas, including rare gases, such as helium, argon, neon, and xenon, and hydrogen.

When the deposition gas contains a raw material gas including an organic silicon compound containing silicon and an oxygen gas, it is preferable that the deposition gas contains the oxygen gas at a percentage not too higher than the theoretical percentage of the oxygen gas required for complete reaction of the raw material gas and the oxygen gas. If the percentage of the oxygen gas is too high, it is difficult to obtain a gas barrier layer required for the present invention. Consequently, in order to obtain a required property as a barrier film, it is preferable that a total amount of an organosilicon compound in the deposition gas is set to be less than a theoretical amount for complete oxidation.

As a representative example, it will be described a case in which hexamethyldisiloxane (organosilicon compound (HMDSO: (CH₃)₆Si₂O) is a raw material gas and oxygen (O₂) is a reactive gas.

When a silicon-oxygen thin film is formed with a roller CVD method by using hexamethyldisiloxane (HMDSO: (CH₃)₆Si₂O) as a raw material gas, and oxygen (O₂) as a reactive gas, a thin film composed of silicon dioxide is produced through the following reaction (1).

(CH₃)₆Si₂O+12O₂→6CO₂+9H₂O²SiO₂ Reaction scheme (1):

In this reaction, 12 moles of oxygen is required for complete oxidation of 1 mole of hexamethyldisiloxane. Thus, the complete reaction of a deposition gas containing 12 moles or more oxygen for each mole of hexamethyldisiloxane will generate a uniform silicon dioxide layer. Therefore, the flow rate of the material gas is adjusted to a rate equal to or less than the theoretical rate for complete reaction so as to maintain an incomplete reaction. That is, less than 12 moles of the oxygen should be provided for each mole of hexamethyldisiloxane, which is lower than the stoichiometric ratio of oxygen.

In an actual roller CVD chamber, the hexamethyldisiloxane, which is the raw material gas, and the oxygen, which is the reactive gas, are supplied from the gas inlets to the deposition region. Thus, even if the quantity of the reactive oxygen gas in moles (flow rate) is 12 times of that of hexamethyldisiloxane, which is the raw material gas, the reaction actually cannot be completely accomplished. A complete reaction is presumed to be accomplished only when oxygen is supplied in a quantity that significantly exceeds the stoichiometric ratio (for example, the mole quantity (flow rate) of oxygen may be set to at least approximately 20 times of that of hexamethyldisiloxane so as to produce silicon oxide through a complete oxidation with a CVD method. Thus, the mole quantity (flow rate) of oxygen is preferably not more than 12 times, which is the stoichiometric ratio, more preferably not more than 10 times that of the hexamethyldisiloxane, which is the raw material gas. With such contents of hexamethyldisiloxane and oxygen, the carbon atoms and hydrogen atoms in the hexamethyldisiloxane that are not completely oxidized are incorporated in a gas barrier layer, enabling to form a desired gas barrier layer. When the mole quantity (flow rate) of oxygen is too small relative to the mole quantity (flow rate) of hexamethyldisiloxane in the deposition gas, the non-oxidized carbon and hydrogen atoms are excessively taken in the gas barrier layer. Thus, the gas barrier layer will have low transparency and it cannot be used as a flexible substrate for a device such as an organic EL element or an organic film solar cell, which is required to have transparency. In this view, the lower limit of the mole quantity (flow rate) of oxygen relative to the mole quantity (flow rate) of hexamethyldisiloxane in the deposition gas is preferably 0.1 times or more of the mole quantity (flow rate) of hexamethyldisiloxane, more preferably 0.5 times or more.

### <2.5.2> Vacuum Level

The pressure (vacuum level) in the vacuum chamber may be appropriately adjusted depending on the type of raw material gas and it is preferably in the range of 0.5 to 100 Pa.

### <2.5.3> Roller Deposition

In the roller CVD method using a roller CVD apparatus as illustrated in FIG. 2, electrical discharge is done between the deposition rollers 31 and 32. Therefore, the electric power to be applied to electrode drums (in FIG. 2, they are provide with the deposition rollers 31 and 32) connected to the power source 51 may be appropriately adjusted depending on the type of the raw material gas and the pressure in the vacuum chamber. Although it is not generalized, a preferred electric power is in the range of 0.1 to 10 kW. Electric power applied within such a range does not generate particles (unwanted particles), and the heat generated during deposition is not excessive and controllable. Thus, heat damage and wrinkles in the resin substrate due to the increase in temperature at the surface of the substrate during deposition do not occur. In addition, it will prevent the damage to the deposition rollers caused by the discharge of large amount of current between the naked deposition rollers after melting of the resin substrate.

The conveying rate (line rate) of the resin substrate 2 may be appropriately adjusted depending on the type of the raw material gas and the pressure in the vacuum chamber, and it is preferably in the range of 0.25 to 100 m/min, more preferably in the range of 0.5 to 20 m/min. If the line rate is within these ranges, wrinkles in the resin substrate due to heat are not easily formed, and the thickness of the formed gas barrier layer is controllable. This is preferable.

FIG. 3 shows an example of a profile of each element in the thickness direction of a gas barrier layer of the present invention by XPS depth profiling.

FIG. 3 is a graph showing an example of a silicon distribution curve, an oxygen distribution curve, and a carbon distribution curve of a gas barrier layer of the present invention.

In FIG. 3, symbols A to D indicate as follows. A represents a carbon distribution curve, B represents a silicon distribution curve, C represents an oxygen distribution curve, and D represents an oxygen-carbon distribution curve. As illustrate in FIG. 3, the gas barrier layer of the present invention has the following structure: as a carbon atomic ratio of the aforesaid gas barrier layer, a maximum value of the carbon atomic ratio is less than 20 at % within the distance range of 89% from the surface in the vertical direction; and the carbon atomic ratio within the distance range of 89% from the surface in the vertical direction has a density gradient, and the density continuously changes (these conditions correspond to the items (1) and (2) stipulated in the present invention.)

In addition, as a carbon atomic ratio of the aforesaid gas barrier layer, the following properties are provided: a maximum value of the carbon atomic ratio is 20 at % or more within the distance range of 90 to 95% from the surface in the vertical direction when a thickness of the gas barrier layer in a vertical direction is set to be 100%; and the carbon atomic ratio is continuously increased (these conditions correspond to the items (3) and (4) stipulated in the present invention.)

FIG. 4 is a graph showing an example of a silicon distribution curve, an oxygen distribution curve, and a carbon distribution curve of a gas barrier layer of a comparative example.

The aforesaid gas barrier layer is formed employing a plasma CVD method using a flat electrode (horizontal conveyance). There are indicated the carbon atomic distribution curve A, the silicon atomic distribution curve B, and the oxygen atomic distribution curve C. In particular, it was produced no continuous change in the density gradient of the carbon atom component.

### (3) Resin Substrate

A resin substrate composing a gas barrier film of the present invention will be described. As a resin substrate, it is not specifically limited as long as it is made of an organic material and it can hold a gas barrier layer having the gas barrier property as described above.

Examples of a resin substrate applicable to the present invention include various resin films such as: polyethylene terephthalate (PET) and polyethylene naphthalate (PEN), polycarbonate (PC), polyallylate, polystyrene (PS), aromatic polyamide, polyether ether ketone, polysulfone, polyether sulfone, polyimide, polyether imide. Further, it can be cited laminated films formed by laminating two or more resins as described above. Preferably used films are, for example, polyethylene terephthalate (PET), polyethylene naphthalate (PEN) and polycarbonate (PC) with respect to the cost or the ease of acquisition.

A thickness of the resin substrate is preferably in the range of about 5 to 500 μm, and more preferably, it is in the range of 25 to 250 μm.

It is preferable that the resin substrate of the present invention is transparent. When the resin substrate is transparent and the formed layer on the resin substrate is also transparent, it becomes a transparent gas barrier film. It is possible to use as a transparent substrate for an electronic device (for example, an organic EL element).

The resin substrate employing the aforesaid resin may be an un-stretched film or a stretched film. In view of increasing strength and preventing thermal expansion, a stretched film is preferable. In addition, retardation can be adjusted by stretching.

The resin substrate according to the present invention can be produced with a generally known film forming method. An example thereof is: to melt the material resin with an extruder; to extrude the melted resin through a ring form die or a T-die; and to cool quickly. Thus, it can produce an un-stretched resin substrate which is substantially amorphous and not oriented. Further, it can produce by the following: to dissolve the material resin in a solvent; to cast on the endless metal-resin support; to dry and to peel off the cast resin. Thus, it can produce an un-stretched resin substrate which is substantially amorphous and not oriented.

A stretched resin substrate can be made by stretched the un-stretched resin substrate with a known method such as one axis stretching method, a tenter type successive two axis stretching method, a tenter type simultaneous two axis stretching method, and a tubular type simultaneous two axis stretching method. These methods can stretch the resin substrate in the flow direction (longitudinal axis: MD) of the resin substrate, or in the vertical direction to the flow direction (transversal axis: TD). The stretching ratio in this case can be suitable selected in accordance with the resin used for the resin substrate. It is preferable that the stretching ratio is in the range of 2 to 10 times in both MD direction and TD direction.

The resin substrate according to the present invention may be subjected to a relax treatment and an off-line thermal treatment in view of size stability. The relax treatment is preferably done: after thermal setting during stretching film forming process in the aforesaid film forming method, and inside of the stretching tenter in TD direction, or after going out of the tenter until the reeling process. The relax treatment is preferably done at a temperature in the range of 80 to 200° C. More preferably, it is done in the range of 100 to 180° C. As a method of the off-line thermal treatment, it is not specifically limited. Examples thereof are: a roller transport method using a plurality of rollers; an air transport method which lift the film by blowing an air to the film (a method in which a heated air is blown on one or both surfaces of the film thorough a plurality of slits; a method using radiation of an infrared ray heater; and a method in which the film is hung down by its own weight, and reeling the film in the down portion. The transport tension in the thermal treatment is preferably set to be low to promote thermal contraction. Thus, the resin substrate will become size stabilized. As a thermal treatment temperature, it is preferable to be in the range of (Tg+50) to (Tg+150° C.). Here, Tg indicates a glass transition temperature of the resin substrate.

The resin substrate according to the present invention may be in-line coated with an undercoat layer coating liquid on one or both surfaces during a film forming process. In the present invention, the undercoat layer coating in the film forming process is called as an in-line undercoating. Examples of a resin used for an undercoat layer coating liquid useful for the present invention are: a polyester resin, an acryl-modified polyester resin, a polyurethane resin, an acryl resin, a vinyl resin, a vinylidene chloride resin, a polyethyleneimine polyvinylidene resin, a polyethyleneimine resin, a polyvinylalcohol resin, a modified polyvinylalcohol resin, and gelatin. These can be preferably used. A conventionally known additive may be added to these undercoat layers. And the aforesaid undercoat layer may be formed with any known coating methods such as: a roller coating method, a gravure coating method, a knife coating method, a dip coating method, and a spray coating method. A preferable coating amount of the aforesaid undercoat layer is in the range of 0.01 to 2 g/m² (in the dry condition).

### [4] Second Gas Barrier Layer

The gas barrier film of the present invention is preferably provided with a second gas barrier layer. The second barrier layer is formed with a polysilazane containing liquid by a wet coating method. The coated layer is dried and irradiated with vacuum ultraviolet rays (VUV rays). Then, a reforming treatment is performed to the formed coated layer.

In the present invention, the second gas barrier layer is formed on the gas barrier layer formed with a roller space discharge plasma chemical vapor deposition method by impressing a magnetic field to the rollers. By this structure, it can bury the minute defects remaining in the gas barrier layer already formed with a gas barrier component of polysilazane of the second gas barrier layer from the upper part. As a result, it can effectively prevent gas purge, and gas barrier property and flexibility can be further improved. This is favorable.

The thickness of the second gas barrier layer is preferably in the range of 1 to 500 nm, more preferably, in the range of 10 to 300 nm. When the thickness of the second gas barrier layer is 1 nm or more, a requested gas barrier property can be exhibited. When it is 500 nm or less, it can prevent film deterioration such as generation of cracks in the dense silicon oxynitride film.

### <4.1> Polysilazane

Polysilazane according to the present invention is a polymer containing a silicon-nitrogen bond in the molecular structure. It is a polymer to become a precursor of silicon oxynitride.

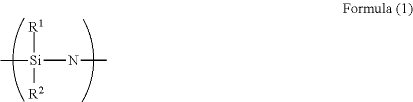

In Formula (1), R¹, R², and R³ each independently represent a hydrogen atom, an alkyl group, an alkenyl group, a cycloalkyl group, an aryl group, an alkylsilyl group, an alkylamino group, or an alkoxy group.

In the present invention, from the viewpoint of the density of the second gas barrier layer, most preferred is a compound having all of R¹, R², and R³ of hydrogen atoms. That is, the polysilazane is most preferably perhydropolysilazane.

Perhydropolysilazane is presumed to have a structure containing a straight chain and a ring structure mainly composed of a 6- and a 8-membered ring. Its molecular weight is about 600 to 2,000 (in polystyrene conversion value, with a gel permuation chromatography) in a number average molecular weight (Mn). It is a material of liquid or solid.

Polysilazane is commercially available in a solution state dissolved in an organic solvent. A commercially available product may be used directly as a coating liquid for producing a polysilazane reforming layer. Examples of commercially available polysilazane are: NN120-20, NAX120-20 and NL120-20, which are supplied by AZ Electronic Materials, Ltd.

The second gas barrier layer is formed with a polysilazane containing coating liquid on the gas barrier layer formed with a roller space discharge plasma chemical vapor deposition method by impressing a magnetic field to the rollers. The coated layer is dried and irradiated with vacuum ultraviolet rays.

As an organic solvent to prepare a polysilazane containing coating liquid, it is preferable to avoid an alcohol solvent or water which easily reacts with polysilazane. Example of an applicable organic solvent are: a hydrocarbon solvent such as an aliphatic hydrocarbon, an alicyclic hydrocarbon, and an aromatic hydrocarbons; an halogenated hydrocarbon solvent; and ether such as an aliphatic ether and an alicyclic ether. Specific examples thereof are: a hydrocarbon such as pentane, hexane, cyclohexane, toluene, xylene, Solvesso™, and turpentine; a halogenated hydrocarbon such as methylene chloride and trichloroethane; and ether such as dibutyl ether, dioxane and tetrahydrofuran. These organic solvents may be chosen in accordance with characteristics, such as solubility of polysilazane, and an evaporation rate of an organic solvent, and a plurality of solvents may be mixed.

A concentration of polysilazane in a polysilazane containing coating liquid for forming a second gas barrier layer is different depending on the thickness of the second gas barrier layer and the pot life of the coating liquid. Preferably, it is in the range of 0.2 to 35 mass %.

In order to promote the conversion to silicon oxynitride, the polysilazane containing coating liquid for forming a second gas barrier layer may contain additives. Examples thereof are: an amine catalyst, and a metal catalyst (Pt compound such as Pt acetyl acetonate, a Pd compound such as propionic acid PD, a Rh compound such as Rh acetyl acetonate). In the present invention, an amine catalyst is particularly preferable. Specific examples of an amine catalyst are: N,N-diethylethanolamine, N,N-dimethylethanolamine, triethanolamine, triethylamine, 3-morpholino-propylamine, N,N,N′,N′-tetramethyl-1,3-diaminopropane, and N,N,N′,N′-tetramethyl-1,6-diaminohexane.

An added amount of these catalyst to polysilazane is preferably in the range of 0.1 to 10 mass % with respect to the total mass of the coating liquid for forming a second gas barrier layer. More preferably, it is in the range of 0.2 to 5 mass %, and still more preferably, in the range of 0.5 to 2 mass %. By making the concentration of a catalyst in this range, it is possible to avoid excessive formation of silanol due to a rapid advance in reaction such as decrease of a layer density and increase of layer defects.

A conventionally known appropriate wet coating method, may be adopted as a coating method of a polysilazane containing coating liquid for forming a second gas barrier layer. Specific examples of a coating method include: a roller coat method, a flow coat method, an inkjet method, a spray coat method, a printing method, a dip coat method, a casting film forming method, a bar coat method and a gravure printing method.

A coating thickness may be appropriately set up according to the purpose. For example, a coating thickness may be set up so that the thickness after being dried is preferably about 50 nm to 2 μm, more preferably, it is in the range of 70 nm to 1.5 μm, still more preferably, it is in the range of 100 nm to 1 μm.

### <4.2> Excimer Treatment

The second gas barrier layer according to the present invention is a process to irradiate a polysilazane containing layer with vacuum ultraviolet (VUV) rays. At least a port of polysilazane is reformed to silicon oxynitride by this process.

Here, it will be described a supposed mechanism of forming a specific composition of SiO_{X}N_{Y} by reforming a polysilazane containing coated layer with a vacuum ultraviolet ray irradiating process. Perhydropolysilazane is taken as an example for explanation.

Perhydropolysilazane can be specified by the composition of “—(SiH₂—NH)ₙ—”. When it is specified by SiOₓN_{y}, it is shown by x=0 and y=1. In order to achieve the condition of x>0, it is required an outer oxygen source. The outer oxygen sources are as follows.

(i) Oxygen or water contained in a polysilazane coating liquid
(ii) Oxygen or water taken in a coated layer from the environment of a coating-drying process
(iii) Oxygen, water, ozone, and singlet oxygen taken in a coated layer from the environment of a vacuum ultraviolet ray irradiating process
(iv) Oxygen or water transferred as a released gas in a coated layer from the substrate side by the heat given in a vacuum ultraviolet ray irradiating process
(v) Oxygen or water taken in a coated layer from the oxidation environment, when the vacuum ultraviolet ray irradiating process is conducted in a non-oxidation environment, and then, the coated layer is transferred from the non-oxidation environment to an oxidation environment.

On the other hand, since it is a very unusual case in which oxidation of N is progressed than oxidation of Si, y has basically un upper limit value of 1.

Based on the relationship of the bond of Si, O and N, x and y are basically in the range of: 2x+3y≦4. In the condition of complete oxidation, y=0, the coated layer becomes to contain a silanol group. There is a case in which 2<x<2.5.

In the following, it will be described a supposed reaction mechanism of forming silicon oxynitride from perhydropolysilazane, and further, forming silicon oxide in the vacuum ultraviolet ray irradiating process.

### (1) Dehydrogenation, and Formation of Si—N Bond Accompanied Thereby

A Si—H bond and a N—H bond in perhydropolysilazane are relatively easily broken by excitation with vacuum ultraviolet ray irradiation. It is supposed that they are bonded again as a Si—N bond in an inactive atmosphere (there is a case of forming a non-bonding site in Si). Namely, it is cured as forming a SiN_{y} composition without-oxidation. In this case, there is no break in the polymer main chain. The break of a Si—H bond or a N—H bond is promoted by the presence of a catalyst or by heat. The broken H will be released out of the film as H₂.

### (2) Formation of Si—O—Si Bond by Hydrolysis and Dehydrocondensation

A Si—N bond in perhydropolysilazane is hydrolyzed with water, and a Si—OH bond is formed by the break of the polymer main chain. Two Si—OH bonds are dehydrocondensed to form a Si—O—Si bond and cured. Although this reaction is taken place in the atmosphere, it is considered that water vapor produced as a released gas from the resin substrate becomes a main water source, the water vapor being released by the irradiation heat in the vacuum ultraviolet ray irradiating process. When ware is excessive, there remain Si—OH bonds which are not dehydrocondensed. As a result, the cured film has a low gas barrier property represented by the composition of SiO_{2.1} to SiO_{2.3}.

### (3) Direct Oxidation by Singlet Oxygen, Formation of Si—O—Si Bond

During the vacuum ultraviolet ray irradiation, when an appropriate amount of oxygen exists in the atmosphere, it will be produced singlet oxygen having very strong oxidation ability. H and N in perhydropolysilazane are substituted with O to form c to result in being cured. It is considered that there is a case in which recombination of bonds occur by the break of the polymer main chain.

(4) Oxidation Accompanied by the Break of Si—N Bond with Vacuum Ultraviolet Ray Irradiation and Excitation

Since the energy of vacuum ultraviolet rays is higher than the bond energy of Si—N bond in perhydropolysilazane, the Si—N bond is broken. When there are oxygen sources such as oxygen, ozone, and water in the surroundings, it is oxidized to form a Si—O—Si bond or a Si—O—N bond. It is considered that there is a case in which recombination of bonds occur by the break of the polymer main chain.

The adjustment of the composition of silicon oxynitride in the polysilazane containing layer irradiated with vacuum ultraviolet rays can be done by controlling the oxidation state with a suitable combination of the oxidation mechanisms of (1) to (4).

In a vacuum ultraviolet ray irradiation process of the present invention, illuminance of the aforesaid vacuum ultraviolet rays which are received at a coated layer surface of a polysilazane coated layer is preferably in the range of 30 to 200 mW/cm², and more preferably, it is in the range of 50 to 160 mW/cm². When it is 30 mW/cm² or more, the reforming efficiency will not be decreased. When it is 200 mW/cm² or less, there will not occur concern of producing ablation in the coated layer or giving damage to the substrate.

An amount of irradiation energy (irradiation amount) of vacuum ultraviolet rays at a polysilazane coated layer surface is preferably in the range of 200 to 10,000 mJ/cm², more preferably, it is in the range of 500 to 5,000 mJ/cm². When it is 200 mJ/cm² or more, sufficient reforming will be done. When it is 10,000 mJ/cm² or less, there will not occur concern of producing crack due to over reforming or thermal deformation of the substrate.

As a vacuum ultraviolet ray source, a rare gas excimer lamp is preferably used. Rare gas atoms such as Xe, Kr, Ar and Ne are called as an inert gas, since they will not form bond to produce a molecule.

Since a Xe excimer lamp emits ultraviolet rays of a single short wavelength of 172 nm, it is excellent in luminous efficiency. Oxygen has a large absorption coefficient to this light, as a result, it can generate a radical oxygen atom species and ozone in high concentration with a very small amount of oxygen.

Moreover, it is known that the light energy of a short wavelength of 172 nm has a high potential to dissociate a bond in an organic substance. Property reform of polysilazane film will be realized in a short time with the high energy which is possessed by this active oxygen, ozone, and ultraviolet ray radiation.

Therefore, compared with a low pressure mercury lamp emitting light of 185 nm and 254 nm wavelength or plasma cleaning, it enables to shorten the process time with high throughput and to decrease the installation space. It can irradiate to an organic material or a plastic substrate which is susceptible to receive damage by heat.

An excimer lamp has a high efficiency in generation of light, as a result, it is possible to make the light switch on by an injection of low electric power. Moreover, it does not emit a light with a long wavelength which will be a factor of temperature increase, but since it emits energy of a single wavelength in a UV region, it has a distinctive feature of suppressing an increase of a surface temperature of an exposure subject. For this reason, it is suitable for flexible film materials, such as polyethylene terephthalate which is supposed to be easily affected by heat.

Oxygen is required for the reaction during ultraviolet ray irradiation. Since a vacuum ultraviolet ray is absorbed by oxygen, efficiency during the step of ultraviolet ray irradiation is likely to decrease. Therefore, irradiation of the vacuum ultraviolet rays is preferably carried out at a concentration of oxygen and water vapor being as low as possible. That is, an oxygen concentration during a vacuum ultraviolet ray irradiation is preferably in the range of 10 to 10,000 ppm, more preferably, it is in the range of 50 to 5,000 ppm, and still more preferably, it is in the range of 1,000 to 4,500 ppm.

As a gas which is used during vacuum ultraviolet ray irradiation and fills an irradiation atmosphere, a dry inactive gas is preferably used. In particular, a dry nitrogen gas is preferable from the viewpoint of cost. The adjustment of an oxygen concentration may be made by measuring a flow rate of an oxygen gas and an inactive gas introduced in an irradiation chamber and by changing a flow rate ratio.

### [5] Each Functional Layer

With respect to the gas barrier film of the present invention, it can provide various functional layers when needed in addition to the constituting layers.

### <5.1> Overcoat Layer

An overcoat layer may be formed on the second gas barrier layer according to the present invention in order to further improve the flexibility. Examples of a preferably used organic material for forming an overcoat layer are: an organic resin of an organic monomer, an oligomer, and a polymer; and an organic-inorganic composite resin layer used a monomer, an oligomer and a polymer of siloxane or silsesquioxane containing an organic group. It is preferable that these organic resins and organic inorganic composite resins contain a polymerizable group or a cross-linking group. After forming a coated layer with an organic resin composition coating liquid containing an organic resin or an organic-inorganic composite resin, and a polymerization initiator, and a cross-linking agent when needed, it is preferable to perform light irradiation or thermal treatment to cure the layer.

### [6] Electronic Device

The gas barrier layer of the present invention is preferably used for a film for an electronic device.

Examples of an electronic device are: an organic electroluminescent panel (organic EL panel), an organic electroluminescent element (organic EL element), an organic photoelectron conversion element, and a liquid crystal display element.

### <6.1> Example of an Organic EL Panel as an Electronic Device

The gas barrier film 1 of the present invention having a constitution as shown in FIG. 1 is used for a sealing film to seal a solar cell, a liquid crystal display element, a resin substrate of an organic EL element, or an organic EL layer.

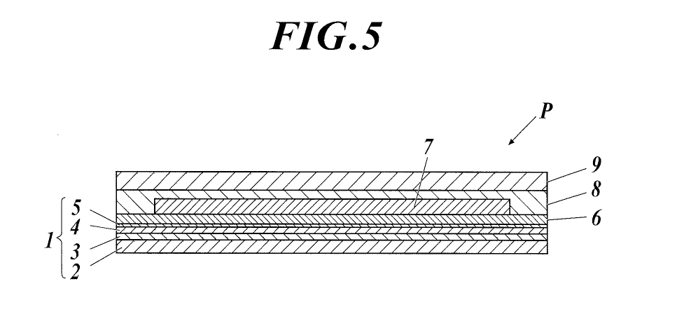

An example of an organic EL panel P is shown in FIG. 5. It is an electronic device using the gas barrier film 1 as a resin substrate.

As shown in FIG. 5, an organic EL panel P is provided with: a gas barrier film 1 of the present invention, a transparent electrode 6 (such as ITO) formed on the gas barrier film 1, an organic EL element 7 (being an electronic device) formed on the gas barrier film 1 through the transparent electrode 6, and an opposing film 9 which is located through an adhesive layer 8 so as to cover the organic EL element 7. In addition, the transparent electrode 6 may be a part of the organic EL element 7.

The transparent electrode 6 and the organic EL element 7 are located on the surface of a gas barrier layer 4 and a second gas barrier layer 5 in this gas barrier film 1.

In the organic EL panel P, the organic EL element 7 is appropriately sealed to avoid exposure to water vapor. Since the organic EL panel P is hardly deteriorated, it is possible to use the organic EL panel P for prolonged period. Thus the lifetime of the organic EL panel P is extended.

Here, the opposing film 9 may be made of a metal film such as an aluminum foil, or made of a gas barrier film of the present invention. When the gas barrier film is employed as the opposing film 9, only required is to direct the surface formed with the gas barrier layer 4 to the organic EL element 7, and to adhered with the adhesion layer 8.

### <6.2> Organic EL Element

In an organic EL panel P, an organic EL element 7 using a gas barrier film 1 as a substrate will be described.

Preferable specific examples of a layer constitution of an organic EL element 7 will now be described below, however, the present invention is not limited to these.

(1) Anode/light emitting layer/cathode
(2) Anode/hole transport layer/light emitting layer/cathode
(3) Anode/light emitting layer/electron transport layer/cathode
(4) Anode/hole transport layer/light emitting layer/electron transport layer/cathode
(5) Anode/anode buffer layer (hole injection layer)/hole transport layer/light emitting layer/electron transport layer/cathode buffer layer (electron injection layer)/cathode

### <Anode>

As an anode (first electrode), a metal having a large work function (4 eV or more), an alloy, and a conductive compound and a mixture thereof are preferably utilized as an electrode substance.

### <Hole Injection Layer>

An electron injection layer (it is also called as “an anode buffer layer”) may be located between a first electrode and a light emitting layer or a hole transport layer. A hole injection layer is a layer located between an electrode and an organic layer in order to decrease an operating voltage and to improve an emission luminance.

### <Hole Transport Layer>

A hole transport layer is a layer containing a hole transport material having a function of transporting a hole. A hole transport layer includes a hole injection layer, and an electron blocking layer in a broad sense. Further, a hole transport layer may be composed of plural layers.

### <Light Emitting Layer>

A light emitting layer is a layer which provide a place of emitting light via an exciton produce by recombination of electrons and holes injected from an electrode or an adjacent layer. The light emitting portion may be either within the light emitting layer or at an interface between the light emitting layer and an adjacent layer thereof.

It is preferable that the light emitting layer incorporates a light emitting dopant (a light emitting dopant compound, a dopant compound, or simply called as a dopant) and a host compound (a matrix material, a light emitting host compound, or simply called as a host).

The light emitting layer is composed of a single layer or plural layers. When the light emitting layer is composed of plural layers, a non-light emitting layer may be placed between each light emitting layer.

### <Electron Transport Layer>

An electron transport layer is composed of a material having a function of transporting an electron.

An electron transport layer includes an electron injection layer, and a hole blocking layer in a broad sense. Further, electron transport layer may be composed of a single layer or plural layers.

### <Electron Injection Layer>

It may be placed an electron injection layer (it is also called as “a cathode buffer layer”) between a cathode (second electrode) and a light emitting layer or an electron transport layer. An electron injection layer is composed of a material having a function of transporting an electron, and it is included in an electron transport layer in a broad sense. An electron injection layer is a layer arranged between an electrode and an organic layer in order to decrease an operating voltage and to improve an emission luminance.

### <Cathode>

As a cathode (second electrode), a metal having a small work function (4 eV or less) (it is called as an electron infective metal), an alloy, a conductive compound and a mixture thereof are utilized as an electrode substance.

### <Production Method of Organic EL Element>

It will be described a forming method of an organic EL element main part (a hole injection layer, a hole transport layer, a light emitting layer, a hole blocking layer, an electron transport layer and an electron injection layer).

A forming method of an organic EL element main part is not specifically limited. It may be formed by using a known method such as a vacuum vapor deposition method and a wet method (it is also called as a wet process).

Examples of a wet process include: a spin coating method, a cast method, an inkjet method, a printing method, a die coating method, a blade coating method, a roll coating method, a spray coating method, a curtain coating method, and a LB method (Langmuir Blodgett method). From the viewpoint of getting a uniform thin layer with high productivity, preferable are method highly appropriate to a roll-to-roll method such as a die coating method, a roll coating method, an inkjet method, and a spray coating method.

A different film forming method may be applied to every organic layer. When a vapor deposition method is adopted for forming each layer, the vapor deposition conditions will change depending on the compounds used. Generally, the following ranges are suitably selected for the conditions, heating temperature of boat: 50 to 450° C., level of vacuum: 1×10⁻⁶ to 1×10⁻² Pa, vapor deposition rate: 0.01 to 50 nm/sec, temperature of substrate: −50 to 300° C., and layer thickness: 0.1 nm to 5 μm, preferably 5 nm to 200 nm.

Formation of organic layers of the present invention is preferably continuously carried out from a hole injection layer to a cathode with one time vacuuming. It may be taken out on the way, and a different layer forming method may be employed. In that case, the operation is preferably done under a dry inert gas atmosphere.

Specific layer constitutions, composing materials and production method of an organic EL element are described in detail in the following and can be referred to: JP-A 2011-238355, JP-A 2013-077585, JP-A 2013-187090, JP-A 2013-229202, JP-A 2013-232320; and JP-A-2014-026853.

### EXAMPLES

Hereafter, the present invention will be described specifically by referring to examples, however, the present invention is not limited to them. In examples, the term “parts” or “%” is used. Unless particularly mentioned, they respectively represent “mass parts” or “mass %”.

### Example 1

### Preparation of Resin Substrate

As a thermoplastic resin substrate (support), it was used a roll type polyester film treated with easy-adhesion processing on both surfaces and having a thickness of 125 μm (polyethylene terephthalate KDL86WA, made by Teijin-Dupont Co., Ltd., in the table, it is indicated as PET) without modification. A surface roughness (based on JIS B 0601) of the resin substrate was measured. It was found that an arithmetic average roughness Ra was 4 nm and ten points average roughness Rz was 320 nm.

### <<Preparation of Resin Substrate Having a Smoothing Layer>>

### [Preparation of Resin Substrate 1 Having a Smoothing Layer]

A coating liquid 1 for forming a smoothing layer as described below was coated on a surface side of the resin substrate placed with a gas barrier layer with a wire bar to make a dry thickness of 4 μm. Subsequently, the coated layer was dried at 80° C. for 3 minutes, then, it was cured with a high pressure mercury lamp under the curing condition of 0.5 J/cm². Thus, Resin substrate having a smoothing layer 1 was prepared.

### (Preparation of Coating Liquid 1 for Forming a Smoothing Layer)

To UV curable resin UNIDIC V-4025 (made by DIC Co. Ltd.) was added a fluoro-oligomer SURFLON S-651 (made by AGC Seimi Chemical, Co. Ltd.) so as to have a solid portion ratio (mass ratio) of UV curable resin/S-651=99.8/0.2. Further, a photo-initiator Irgacure 184 (made by BASF Japan Co. Ltd.) was added so as to have a solid portion ratio (mass ratio) of UV curable resin/photo-initiator=95/5. Then, it was diluted with a solvent MEK used as a solvnet. Thus, a coating liquid 1 for forming a smoothing layer was prepared (NV 30 mass %).

### [Preparation of Resin Substrates 2 to 5, and 11 Each Having a Smoothing Layer]

A coating liquid 2 for forming a smoothing layer was prepared in the same way as preparation of a coating liquid 1 for forming a smoothing layer in the aforesaid preparation of a resin substrate 1 having a smoothing layer, except that S-651 in the coating liquid 1 for forming a smoothing layer was changed to hydroxyethyl methacrylate (HEMA: Light ester HO-250, made by Kyoeisha Co. Ltd.). Resin substrates 2 to 5, and 11 having a smoothing layer were prepared using the prepared coating liquid 2 for forming a smoothing layer.

### [Preparation of Resin Substrate 6 Having a Smoothing Layer]

A coating liquid 6 for forming a smoothing layer was prepared in the same way as preparation of a coating liquid 1 for forming a smoothing layer in the aforesaid preparation of a resin substrate 1 having a smoothing layer, except that S-651 in the coating liquid 1 for forming a smoothing layer was not used and the UV curable resin was changed to a mixture of V-4025 with A-BPEF (fluorene containing acrylate: made by Shin-Nakamura Chemical, Co. Ltd.) having a mass ratio of 50/50. A resin substrate 6 having a smoothing layer was prepared using the prepared coating liquid 6 for forming a smoothing layer.

### [Preparation of Resin Substrate 7 Having a Smoothing Layer]

A coating liquid 7 for forming a smoothing layer was prepared in the same way as preparation of a coating liquid 1 for forming a smoothing layer in the aforesaid preparation of a resin substrate 1 having a smoothing layer, except that S-651 in the coating liquid 1 for forming a smoothing layer was not used and the UV curable resin was changed to ZX-212 (T&K-TOKA Co. Ltd.). A resin substrate 7 having a smoothing layer was prepared using the prepared coating liquid 7 for forming a smoothing layer.

### [Preparation of Resin Substrate 8 Having a Smoothing Layer]

A coating liquid 8 for forming a smoothing layer was prepared in the same way as preparation of a coating liquid 1 for forming a smoothing layer in the aforesaid preparation of a resin substrate 1 having a smoothing layer, except that S-651 in the coating liquid 1 for forming a smoothing layer was changed to FA-512M (dicyclopentenyl oxyethyl methacrylate: made by Hitachi Chemical, Co. Ltd.), and added mass ratio of UV curable resin/FA-512M was changed to 82/18. A resin substrate 8 having a smoothing layer was prepared using the prepared coating liquid 8 for forming a smoothing layer.

### [Preparation of Resin Substrate 9 Having a Smoothing Layer]

A coating liquid 9 for forming a smoothing layer was prepared in the same way as preparation of a coating liquid 6 for forming a smoothing layer in the aforesaid preparation of a resin substrate 6 having a smoothing layer, except that the mass ratio of the UV curable resin V-4025 to A-BPEF (fluorene containing acrylate: made by Shin-Nakamura Chemical, Co. Ltd.) was changed to 75/25. A resin substrate 9 having a smoothing layer was prepared using the prepared coating liquid 9 for forming a smoothing layer.

### [Preparation of Resin Substrate 10 Having a Smoothing Layer]

A coating liquid 10 for forming a smoothing layer was prepared in the same way as preparation of a coating liquid 1 for forming a smoothing layer in the aforesaid preparation of a resin substrate 1 having a smoothing layer, except that S-651 in the coating liquid 1 for forming a smoothing layer was not used and the UV curable resin was changed to LCH1559 (Silica containing hybrid hard coating agent: made by Toyochem Co., Ltd.). A resin substrate 10 having a smoothing layer was prepared using the prepared coating liquid 10 for forming a smoothing layer.

### [Preparation of Resin Substrate 12 Having a Smoothing Layer]

A coating liquid 12 for forming a smoothing layer was prepared in the same way as preparation of a coating liquid 2 for forming a smoothing layer in the aforesaid preparation of a resin substrate 2 having a smoothing layer, except that the mass ratio of the UV curable resin/HEMA was changed to 95/5. A resin substrate 12 having a smoothing layer was prepared using the prepared coating liquid 12 for forming a smoothing layer.

### [Preparation of Resin Substrate 13 Having a Smoothing Layer]

A coating liquid 13 for forming a smoothing layer was prepared in the same way as preparation of a coating liquid 2 for forming a smoothing layer in the aforesaid preparation of a resin substrate 2 having a smoothing layer, except that the mass ratio of the UV curable resin/HEMA was changed to 99/1. A resin substrate 13 having a smoothing layer was prepared using the prepared coating liquid 13 for forming a smoothing layer.

### [Preparation of Resin Substrate 14 Having a Smoothing Layer]

A coating liquid 14 for forming a smoothing layer was prepared in the same way as preparation of a coating liquid 2 for forming a smoothing layer in the aforesaid preparation of a resin substrate 12 having a smoothing layer, except that HEMA in the coating liquid 2 for forming a smoothing layer was changed to CB-1 (2-methacryloyoxy ethyl phthalic acid: Shin-Nakamura Chemical, Co. Ltd.), and the added mass ratio of the UV curable resin/CB-1 was changed to 92/8. A resin substrate 14 having a smoothing layer was prepared using the prepared coating liquid 14 for forming a smoothing layer.

### [Preparation of Resin Substrate 15 Having a Smoothing Layer]

A coating liquid 15 for forming a smoothing layer was prepared in the same way as preparation of a coating liquid 2 for forming a smoothing layer in the aforesaid preparation of a resin substrate 2 having a smoothing layer, except that V-4025 in the coating liquid 2 for forming a smoothing layer was changed to LCH1559 (Silica containing hybrid hard coating agent: made by Toyochem Co., Ltd.), HEMA was changed to a mixture of phosphoric acid acrylate: light acrylate P-1A (made by Kyoeisha Chemical, Co. Ltd.), and further, the added mass ratio of the UV curable resin/P-1 was changed to 99/1. A resin substrate 15 having a smoothing layer was prepared using the prepared coating liquid 15 for forming a smoothing layer.

### [Preparation of Resin Substrate 16 Having a Smoothing Layer]

A coating liquid 16 for forming a smoothing layer was prepared in the same way as preparation of a coating liquid 2 for forming a smoothing layer in the aforesaid preparation of a resin substrate 2 having a smoothing layer, except that V-4025 in the coating liquid 2 for forming a smoothing layer was changed to LCH1559 (Silica containing hybrid hard coating agent: made by Toyochem Co., Ltd.), HEMA was changed to a mixture of isobornyl methacrylate: light ester IB-X (made by Kyoeisha Chemical, Co. Ltd.), and further, the added mass ratio of the UV curable resin/IB-X was changed to 96/4. A resin substrate 16 having a smoothing layer was prepared using the prepared coating liquid 16 for forming a smoothing layer.

### [Preparation of Resin Substrate 17 Having a Smoothing Layer]

A coating liquid 17 for forming a smoothing layer was prepared in the same way as preparation of a coating liquid 2 for forming a smoothing layer in the aforesaid preparation of a resin substrate 2 having a smoothing layer, except that V-4025 in the coating liquid 2 for forming a smoothing layer was changed to LCH1559 (Silica containing hybrid hard coating agent: made by Toyochem Co., Ltd.), HEMA was changed to GMA (light ester G glycidyl methacrylate, made by Kyoeisha Chemical, Co. Ltd.), and further, the added mass ratio of the UV curable resin/light ester G was changed to 97/3. A resin substrate 17 having a smoothing layer was prepared using the prepared coating liquid 17 for forming a smoothing layer.

### [Preparation of Resin Substrate 18 Having a Smoothing Layer]

A coating liquid 18 for forming a smoothing layer was prepared in the same way as preparation of a coating liquid 2 for forming a smoothing layer in the aforesaid preparation of a resin substrate 2 having a smoothing layer, except that V-4025 in the coating liquid 2 for forming a smoothing layer was changed to LCH1559 (Silica containing hybrid hard coating agent: made by Toyochem Co., Ltd.), HEMA was changed to FA-512M (dicyclopentenyl oxyethyl methacrylate: made by Hitachi Chemical, Co. Ltd.), and further, the added mass ratio of the UV curable resin/FA-512M was changed to 99/1. A resin substrate 18 having a smoothing layer was prepared using the prepared coating liquid 18 for forming a smoothing layer.

### [Preparation of Resin Substrates 19, and 21 to 25 Each Having a Smoothing Layer]

Resin substrates 19, and 21 to 25 having a smoothing layer were prepared in the same way as preparation of a resin substrate 18 by using a coating liquid 18 for forming a smoothing layer in the aforesaid preparation of a resin substrate 18 having a smoothing layer, except that by replacing the resin substrate of polyethylene terephthalate with a polyester naphthalate film treated with easy-adhesion processing on both surface and having a thickness of 125 μm (Q65FWA, made by Teijin-Dupont Co. Ltd. It is named as PEN in Table 1).

### [Preparation of Resin Substrate 20 Having a Smoothing Layer]

A resin substrate 20 having a smoothing layer was prepared in the same way as preparation of a resin substrate 18 by using a coating liquid 18 for forming a smoothing layer in the aforesaid preparation of a resin substrate 18 having a smoothing layer, except that by replacing the resin substrate from polyethylene terephthalate with a polycarbonate film having a thickness of 100 μm (WR-S5, made by Teijin Chemicals Ltd. It is named as PC in Table 1).

### <<Preparation of Gas Barrier Film>>

### [Preparation of Gas Barrier Film 1]

By employing a roller space discharge plasma CVD apparatus with impressing a magnetic field to the rollers as described in FIG. 2, a smoothing layer was formed on a resin substrate 1. On that surface having a smoothing layer was formed a gas barrier layer with a method as described below. Thus, a gas barrier film 1 was prepared. This layer forming method is abbreviated d as a roller CVD method.

The above-described resin substrate 1 having a smoothing layer was set to a production apparatus 31 as illustrated in FIG. 2 in such a manner that an opposite surface to the smoothing layer was in contact with a deposition roller. Then, it was transported. Subsequently, a magnetic-filed was impressed to a space between a deposition roller 31 and a deposition roller 32. At the same time, discharge was induced in the space between a deposition roller 31 and a deposition roller 32 to generate plasma. Subsequently, it was supplied a mixed gas composed of a deposition gas (hexamethyldisiloxane (HMDSO), as a raw material gas) and a reaction gas (oxygen gas, it works as a discharge gas) into the discharge region. A gas barrier layer with a thickness of 500 nm was formed on the substrate with a plasma CVD method. Thus, a gas barrier film 1 was produced.

### (Layer Forming Conditions)

Supplying amount of raw material gas (hexamethylene disiloxane, HMDSO): 50 sccm (Standard Cubic Centimeter per Minutes)

Supplying amount of oxygen gas (O₂): 500 sccm

Vacuum level in vacuum chamber: 3 Pa

Impressed electric power from power source for plasma generation: 0.8 kW

Frequency of power source for plasma generation: 70 kHz

Transport rate of resin substrate having a smoothing layer: 0.8 m/min

### [Preparation of Gas Barrier Film 2]

In accordance with the conditions described below and by using a plasma discharge method, it was prepared a gas barrier film 2 having a thickness of 500 nm and composed of a first ceramic layer and a second ceramic layer on a surface of the resin substrate 2 having a smoothing layer. This film forming method is called as a CVD method.

### (Formation of First Ceramic Layer)

### <Mixed Gas Composition for Forming First Ceramic Layer>

| | |
|---|---|
| Discharge gas: nitrogen gas | 94.9 volume % |
| Thin film forming gas: tetraethoxysilane | 0.5 volume % |
| Added gas: oxygen gas | 5.0 volume % |

### (Film Forming Condition of First Ceramic Layer)

### <First Electrode Side>

Type of power source: 80 kHz, made by Oyo Electronic, Co. Ltd.

Frequency: 80 kHz

Output density: 8 W/cm²

Electrode temperature: 120° C.

### <Second Electrode Side>

Type of power source: CF-5000-13M, 13.56 MHz, made by Pearl Corporation

Frequency: 13.56 MHz

Output density: 10 W/cm²

Electrode temperature: 90° C.

### (Formation of Second Ceramic Layer)

### <Mixed Gas Composition for Forming Second Ceramic Layer>

| | |
|---|---|
| Discharge gas: nitrogen gas | 94.9 volume % |
| Thin film forming gas: tetraethoxysilane | 0.1 volume % |
| Added gas: oxygen gas | 5.0 volume % |

### (Film Forming Condition of Second Ceramic Layer)

### <First Electrode Side>

Type of power source: PHF-6k, 100 kHz (continuous mode), made by HAIDEN LABORATORY, Co., Ltd.

Frequency: 100 kHz

Output density: 10 W/cm²

Electrode temperature: 120° C.

### <Second Electrode Side>

Type of power source: CF-5000-13M, 13.56 MHz, made by Pearl Corporation

Frequency: 13.56 MHz

Output density: 10 W/cm²

Electrode temperature: 90° C.

### [Preparation of Gas Barrier Film 3]

In accordance with the conditions described below and by using a conventionally known sputter method, it was prepared a gas barrier film 3 formed with a gas barrier layer composed of SiO₂ and having a thickness of 500 nm on a surface of the resin substrate 2 having a smoothing layer. This film forming method is called as a sputter method.

### [Preparation of Gas Barrier Film 4]

By using a vacuum deposition device, a resistance heating boat provided with SiO₂ was heated by applying an electric current. It was prepared a gas barrier film 4 formed with a gas barrier layer composed of SiO₂ and having a thickness of 500 nm on a surface of the resin substrate 2 having a smoothing layer with a vapor deposition rate of 1 to 2 nm/sec.

### [Preparation of Gas Barrier Film 5]

By using a PHPS-excimer method, it was prepared a gas barrier film 5 formed with a gas barrier layer having a thickness of 300 nm on a surface of the resin substrate 2 having a smoothing layer. This film forming method is called as a PHPS-excimer method (in Table 1, it is simply indicated as an excimer method)

### (Formation of SiO₂ Film Composed of Polysilazane)

### <Preparation of Coating Liquid for Forming Polysilazane Layer>

A dibutyl ether solution containing 10 mass % of perhydropolysilazane (AQUAMICA NN120-10, non-catalysis type made by AZ Electronic Materials, Ltd.) was used for a coating liquid for forming a polysilazane layer.

### <Formation of Polysilazane Layer>

The prepared coating liquid for forming a polysilazane layer as described above was coated with a wire bar so that the dried (average) thickness became 300 nm. The coated layer was treated under the condition of temperature 85° C. and relative humidity 55% for one minute to dry. The sample was further kept under an atmosphere of temperature 25° C. and relative humidity 10% (due point: −8° C.) for 10 minute to perform a dehumidification treatment and to form a polysilazane layer.

<Formation of Gas Barrier Layer: Silica Conversion Treatment of Polysilazane Layer with UV Rays>

Subsequently, the formed polysilazane layer was subjected to a silica conversion treatment with a UV apparatus as described below, which was installed in a vacuum chamber and the inner pressure of the apparatus was adjusted.

### <UV Ray Irradiation Apparatus>

Apparatus: Excimer irradiation apparatus MODEL: MECL-M-1-200, made by M. D. COM. Inc.

Wavelength: 172 nm

Enclosed gas in the lamp: Xe

### <Reforming Treatment Conditions>

The sample fixed on the movable stage was subjected to a reforming treatment under the following conditions to form a gas barrier layer and a gas barrier film 5 was prepared.

Excimer light strength: 130 mW/cm² (172 nm)

Distance between the sample and the light source: 1 mm

Stage heating temperature: 70° C.

Oxygen density in the irradiation apparatus: 1.0%

Excimer irradiation time: 5 seconds

### [Preparation of Gas Barrier Films 6 to 20]

Gas barrier films 6 to 20 were prepared in the same way as preparation of the aforesaid gas barrier film 1 except that the resin substrate 1 having a smoothing layer was changed to resin substrates 6 to 20 each having a smoothing layer and a gas barrier was formed on the surface of the resin substrate having a smoothing layer with a roller CVD method.

### [Preparation of Gas Barrier Film 21]

By using the prepared gas barrier film 19 as described above, an overcoat layer was further formed on the gas barrier layer in accordance with the following method. Thus, a gas barrier film 21 was prepared.

### (Formation of Overcoat Layer)

Washin coat MP6103 (made by Washin Chemical Industry, Co. Ltd.) was coated on the gas barrier layer of the gas barrier film 19 under the condition that the dried thickness became 500 nm. Then it was dried at 120° C. for 3 minutes to form an overcoat layer.

### [Preparation of Gas Barrier Film 22]

By using the aforesaid gas barrier film 19, on the formed gas barrier layer was prepared a second gas barrier layer having a thickness of 300 nm with a PHPS-Excimer method in the same way as used for preparing the aforesaid gas barrier film 5. Thus, a gas barrier film 22 was prepared.

### [Preparation of Gas Barrier Film 23]

By using the aforesaid gas barrier film 19, on the formed gas barrier layer was further prepared a gas barrier layer having the same composition (a second gas barrier layer) having a thickness of 500 nm. Thus, it was prepared a gas barrier film 23 with a gas barrier layer having a total thickness of 1,000 nm.

### [Preparation of Gas Barrier Film 24]

By using the aforesaid gas barrier film 22 prepared by laminating a gas barrier layer and a second gas barrier layer, an overcoat layer was formed on the second gas barrier layer in accordance with the following method. Thus, a gas barrier film 24 was produced.

(Formation of Overcoat layer)

Washin coat MP6103 (made by Washin Chemical Industry, Co. Ltd.) was coated on the second gas barrier layer of the gas barrier film 22 under the condition that the dried thickness became 500 nm. Then it was dried at 120° C. for 3 minutes to form an overcoat layer.

### [Preparation of Gas Barrier Film 25]

By using the aforesaid gas barrier film 22 prepared by laminating a gas barrier layer and a second gas barrier layer, an overcoat layer was formed on the second gas barrier layer in accordance with the following method. Thus, a gas barrier film 25 was produced.

### (Formation of Overcoat Layer)

Graska HPC7003 (made by JSR Co.) was coated on the second gas barrier layer of the gas barrier film 22 under the condition that the dried thickness became 500 nm. Then it was dried at 120° C. for 3 minutes to form an overcoat layer.

The compositions of the gas barrier films produced above are respectively shown in Table 1.

TABLE 1

| | | Smoothing layer | | | | | | | | Second | | |
|---|---|---|---|---|---|---|---|---|---|---|---|---|
| | | | | Reactive | | | | | Gas barrier | gas barrier | Overcoat | |
| | Resin | | Inorganic | diluting | Addition | | | | layer | layer | layer | |
| *1 | substrate | Resin | particle | agent | (mass %) | Solvent | *2 | *3 | Method | Method | Resin | Remarks |
| 1 | PET | V-4025 | — | S-651 | 0.2 | MEK | 23 | 0.4 | Roller CVD | — | — | *4 |
| 2 | PET | V-4025 | — | HEMA | 0.2 | MEK | 31 | 0.9 | CVD | — | — | *4 |
| 3 | PET | V-4025 | — | HEMA | 0.2 | MEK | 31 | 0.9 | Sputter | — | — | *4 |
| 4 | PET | V-4025 | — | HEMA | 0.2 | MEK | 31 | 0.9 | Vapor | — | — | *4 |
| | | | | | | | | | deposition | | | |
| 5 | PET | V-4025 | — | HEMA | 0.2 | MEK | 31 | 0.9 | Excimer | — | — | *4 |
| 6 | PET | V-4025/ | — | — | — | MEK | 43 | 1.8 | Roller CVD | — | — | *4 |
| | | A-BPEF | | | | | | | | | | |
| | | (50/50) | | | | | | | | | | |
| 7 | PET | ZX-212 | — | — | — | MEK | 45 | 0.3 | Roller CVD | — | — | *4 |
| 8 | PET | V-4025 | — | FA-512M | 13.0 | MEK | 48 | 1.6 | Roller CVD | — | — | *4 |
| 9 | PET | V-4025/ | — | — | — | MEK | 38 | 1.2 | Roller CVD | — | — | *5 |
| | | A-BPEF | | | | | | | | | | |
| | | (75/25) | | | | | | | | | | |
| 10 | PET | LCH1559 | Present | — | — | MEK | 31 | 1.6 | Roller CVD | — | — | *5 |
| 11 | PET | V-4025 | — | HEMA | 0.2 | MEK | 31 | 0.9 | Roller CVD | | — | *5 |
| 12 | PET | V-4025 | — | HEMA | 5.0 | MEK | 35 | 1.1 | Roller CVD | — | — | *5 |
| 13 | PET | V-4025 | — | HEMA | 1.0 | MEK | 34 | 1.0 | Roller CVD | — | — | *5 |
| 14 | PET | V-4025 | — | CB-1 | 8.0 | MEK | 39 | 1.4 | Roller CVD | — | — | *5 |
| 15 | PET | LGH1559 | Present | P-1A(N) | 1.0 | MEK | 36 | 1.3 | Roller CVD | — | — | *5 |
| 16 | PET | LCH1559 | Present | IB-X | 4.0 | MEK | 39 | 1.5 | Roller CVD | — | — | *5 |
| 17 | PET | LCH1559 | Present | GMA | 3.0 | MEK | 38 | 1.2 | Roller CVD | — | — | *5 |
| 18 | PET | LCH1558 | Present | FA-512M | 1.0 | MEK | 36 | 0.9 | Roller CVD | — | — | *5 |
| 19 | PEN | LCH1559 | Present | FA-512M | 1.0 | MEK | 36 | 0.9 | Roller CVD | — | — | *5 |
| 20 | PC | LCH1559 | Present | FA-512M | 1.0 | MEK | 36 | 0.9 | Roller CVD | — | — | *5 |
| 21 | PEN | LCH1559 | Present | FA-512M | 1.0 | MEK | 36 | 0.9 | Roller CVD | — | MP6103 | *5 |
| 22 | PEN | LGH1559 | Present | FA-512M | 1.0 | MEK | 36 | 0.9 | Roller CVD | Excimer | — | *5 |
| 23 | PEN | LCH1559 | Present | FA-512M | 1.0 | MEK | 36 | 0.9 | Roller CVD | Roller CVD | — | *5 |
| 24 | PEN | LCH1559 | Present | FA-512M | 1.0 | MEK | 36 | 0.9 | Roller CVD | Excimer | MP6103 | *5 |
| 25 | PEN | LCH1559 | Present | FA-512M | 1.0 | MEK | 36 | 0.9 | Roller CVD | Excimer | Graska | *5 |

P-1A(N): Light acrylate P-1A(N)
IB-X: Light ester IB-X
*1: Gas Barrier Film No.
*2: Dispersion component of surface free energy (mN/m)
*3: Arithmetic average roughness Ra(nm)
*4: Comparative example
*5: Present invention

Each composing element described in abbreviation name and the details of the measuring method for dispersion component of surface free energy are shown in the following.

### (Resin Materials)

PET: Polyethylene terephthalate

PEN: Polyethylene naphthalate

PC: Polycarbonate

### (Smoothing Layer)

### <Resin>

V-4025: UV curable resin UNIDIC V-4025 (made by DIC Co. Ltd.)

Fluorene containing acrylate: A-BPEF (made by Shin-Nakamura Chemical, Co. Ltd.)

ZX-212 (TOKA): Fluoro hard coat agent

LCH1559 (made by Toyochem Co., Ltd.): Silica containing hybrid hard coating agent

### <Reactive Diluting Agent>

HEMA: Hydroxyethyl methacrylate (Light ester HO-250, made by Kyoeisha Co. Ltd.)

Phosphoric acid acrylate: Light acrylate P-1A (made by Kyoeisha Chemical, Co. Ltd.)

CB-1: 2-methacryloyoxy ethyl phthalic acid (made by Shin-Nakamura Chemical, Co. Ltd.)

Isobornyl methacrylate: Light ester IB-X (made by Kyoeisha Chemical, Co. Ltd.)

GMA: Light ester G glycidyl methacrylate (made by Kyoeisha Chemical, Co. Ltd.)

FA-512M: Dicyclopentenyl oxyethyl methacrylate (made by Hitachi Chemical, Co. Ltd.)

### (Overcoat Layer)

MP6103: Washin coat MP6103 (made by Washin Chemical, Co. Ltd.)

Graska: Graska HPC7003 (made by JSR Co. Lyd)

### <<Evaluation>>

### (Measurement of Dispersion Component of Surface Free Energy)

Measurement of dispersion component of surface free energy was done after placing the resin substrate having a smoothing layer under the environment of 23° C. and 50% RH for 24 hours. The dispersion component (γSD) of the surface free energy of the present invention was measured with the following method.

The contact angle of the produced smoothing layer surface with 3 kinds of liquids (water, nitromethane and diiodomethane selected as standard liquids) was measured with an automatic contact angle measuring apparatus CA-V Type (made by Kyowa Interface Science, Co. Ltd.). A γSH value was calculated based on the following scheme, and a dispersion component γSD, a polar componentγSP, and a hydrogen bond component γSH (mN/m) of the surface free energy of the smoothing layer were obtained. In addition, the contact angle was obtained by dropping about 3 μl of standard liquids on the smoothing layer surface under the environment of 23° C. and 50% RH, then it was measured the value at 100 msec after reaching the droplet to the surface. The measured value was an average of N=5.

γL·(1+cos θ)/2=(γSD·γLD)^{1/2}+(γSP·γLP)^{1/2}+(γSH·γLH)^{1/2}

In the scheme:

γL: Surface tension of liquid

θ: Contact angle of liquid with solid

γSD, γSP and γSH: Dispersion, polar, hydrogen bond component of surface free energy of solid

γLD, γLP and γLH: Dispersion, polar, hydrogen bond component of surface free energy of liquid

γL=γLD+γLP+γLH

γS=γSD+γSP+γSH

In addition, as three components (γSD, γSP and γSH) of surface free energy of standard liquids, by using the following values, and by solving 3 simultaneous equation based on each contact angle value, each component value (γSD, γSP and γSH) of the surface free energy of the solid was determined.

[Water (29.1, 1.3, 42.4); Nitromethane (18.3, 17.7, 0); and Diiodomethane (46.8, 4.0, 0)]

### <<Measurement of and Evaluation of the Properties of Gas Barrier Film>>

### [Atomic Distribution Profile (XPS Data) Measurement]

XPS depth profile measurement of the produced gas barrier film was done using the following conditions. A silicon atomic distribution curve, an oxygen atomic distribution curve, and a carbon atomic distribution curve were obtained.

Etching ion species: Argon (Ar⁺)

Etching rate (SiO₂ thermal oxidation conversion value): 0.05 nm/sec

Etching interval (SiO₂ conversion value): 10 nm

X-ray photoelectron spectrometer: “VG Theta Probe” made by Thermo Fisher Scientific, Co. Ltd.

Irradiated X-ray: Single crystal spectrum AlKα

X-ray spot and its size: an oval, 800×400 μm

In Table 2, there are indicated the following: maximum at % of silicon atom in the entire region of the gas barrier layer; maximum at % of oxygen atom in the entire region of the gas barrier layer; maximum at % of carbon atom from the surface of the gas barrier layer to the distance region of 89% in the vertical direction, and the presence or absence of the region in which the carbon atomic ratio changes continuously; and maximum at % of carbon atom in the distance region of 90 to 95% from the surface of the gas barrier layer in the vertical direction (in the distance region of 5 to 10% from the surface contacting the resin substrate in the vertical direction), and the presence or absence of the region in which the carbon atomic ratio changes continuously.

Based on the measured data obtained with the aforesaid conditions, the properties of the gas barrier film 17 of the present invention were shown in FIG. 3, and the properties of the gas barrier film 2 of the comparative example were shown in FIG. 4 for showing examples of a silicon distribution curve, an oxygen distribution curve and a carbon distribution curve by taking the distance from the surface of the gas barrier layer as the horizontal axis.

They were described in Table 1 and Table 2.

### [Measurement of Water Vapor Transmission Coefficient (WVTR)]

A water vapor transmission coefficient (WVTR) of a gas barrier film was measured according to the Ca measuring method as shown in the following.

### (Production Device of a Sample for Water Vapor Barrier Property Evaluation)

Vapor deposition apparatus: Vacuum vapor deposition apparatus JEE-400 (made by JEOL Ltd.)

Constant temperature and humidity oven: Yamato Humidic Chamber IG47M

### <Raw Material>

Metal reacting with water to be corroded: calcium (powder)

Water vapor impermeable metal: aluminum (φ: 3 to 5 mm, grain)

### (Preparation of a Sample for Water Vapor Barrier Property Evaluation)

By using a vapor deposition apparatus (Vacuum vapor deposition apparatus JEE-400, made by JEOL Ltd.), it was vapor deposited metal calcium having a size of 12 mm×12 mm through a mask on a gas barrier forming surface of each gas barrier film. At this moment, a vapor deposited thickness was made to be 80 nm.

Subsequently, the mask was taken off while keeping the vacuum condition, and aluminum was vapor deposited on whole one side of the sheet to perform a temporal sealing. Then, the vacuum condition was released, and it was immediately transferred to the dry nitrogen atmosphere. On the aluminum deposited surface was bonded a quartz glass piece having a thickness of 0.2 mm thorough a UV curable resin for sealing (made by Nagase Chemtex, Co. Ltd.). It was irradiated with UV rays to perform curing adhesion and to achieve full sealing. Thus, it was produced a sample for water vapor barrier property evaluation.

The produced sample was kept under high temperature and high humidity condition of 60° C. and 90% RH. The corrosion proceeding state of metal calcium in relation to the keeping time was observed. The observation was done every 1 hour from the beginning till 6 hours, then, it was done every 3 hours till 24 hours. Then, the observation was done every 6 hours till 48 hours, and every 12 hours thereafter. The corroded area of metal calcium in a metal calcium deposited area of 12 mm×12 mm was calculated as a percent (%). The time needed to achieve 1% of the corroded area of metal calcium was obtained by interpolation with a straight line based on the observation results. By using relationship between: vapor deposition area of metal calcium, an amount of water vapor required to corrode 1% area of metal calcium, and the time needed for achieving that, a water vapor transmission coefficient of each gas barrier film was calculated.

[Evaluation of Adhesion (Evaluation of Sample Immediately after Production)]

Evaluation of adhesion of a gas barrier film was done with a grid test conformed with the description of JIS K 5600-5 and 6 (2004 edition).

On a surface of a gas barrier film formed with a gas barrier layer, there were produced 100 pieces of grids having a square of 1 mm by using a cutter knife to attain the resin substrate with a cutter guide having a 1 mm interval. A cellophane adhesive tape (CT405AP-18, 18 mm width, made of Nichiban Co. Ltd.) was bonded to the cut surface. Then the tape was fully adhered to the surface by pressing with a rubber eraser. Then, the tape was peeled off in the vertical direction. The degree of remaining gas barrier layer on the resin substrate surface was measured against the 100 grids. Evaluation of adhesion was done according to the following criteria.

◯: The number of peeled off grids in the grid test is 4 or less.

◯Δ: The number of peeled off grids in the grid test is in the range of 5 to 10.

Δ: The number of peeled off grids in the grid test is in the range of 11 to 15.

ΔX: The number of peeled off grids in the grid test is in the range of 16 to 20.

X: The number of peeled off grids in the grid test is in the range of 21 to 30.

XX: The number of peeled off grids in the grid test is 31 or more.

### [Evaluation of Durability]

As a first step, each gas barrier film was subjected to a high temperature and high humidity treatment by keeping under the conditions of temperature of 85° C. and relative humidity of 50% for 3,000 hours.

Subsequently, as a second step, the gas barrier film was subjected to a bending test by winding around a metal cylinder so as to place the gas barrier surface to be outside, and left for 1 minute.

The gas barrier film conducted with the above-described treatments was subjected to measurement of water vapor transmission coefficient (WVTR) and evaluation of adhesion in the same method as described above.

In addition, the radius of curvature in the bending test corresponds to a half of the diameter of a rod. When the number of winding of the gas barrier film was large, the radius of curvature R was defined as a half of diameter of after winding the gas barrier film. The bending test was done with R of 8 mm.

The obtained results are shown in Table 2.

TABLE 2

| | XPS | | | | | | | | | | |
|---|---|---|---|---|---|---|---|---|---|---|---|
| | | | C | | | | | | | | |
| | | | Surface to 89% | | 90 to 95% | | Immediate evaluation | | *2 | | |
| | Si | O | region | | Region | | WVTR | | WVTR | | |
| | Maximum | Maximum | Maximum | | Maximum | | Ca | | Ca | | |
| | value | Value | value | Continuous | value | Continuous | Evaluation | | Evaluation | | |
| *1 | (at %) | (at %) | (at %) | change | (at %) | change | (g/m² · 24 h) | Adhesion | (g/m² · 24 h) | Adhesion | Remarks |
| 1 | 33 | 62 | 5 | Yes | 2 | Yes | 2.0 × 10⁻⁴ | Δ x | 2.5 × 10⁻¹ | x x | *3 |
| 2 | 31 | 65 | 4 | No | 8 | No | 6.0 × 10⁻⁴ | Δ x | 1.2 × 10⁻¹ | x x | *3 |
| 3 | 32 | 68 | 0 | No | 0 | No | 1.5 × 10⁻⁴ | Δ x | 3.5 × 10⁻² | x x | *3 |
| 4 | 34 | 66 | 0 | No | 0 | No | 4.0 × 10⁻⁴ | Δ x | 7.0 × 10⁻¹ | x x | *3 |
| 5 | 31 | 69 | 0 | No | 0 | No | 2.0 × 10⁻⁴ | ∘ | 1.0 × 10⁻² | x x | *3 |
| 6 | 25 | 64 | 11 | Yes | 15 | Yes | 3.0 × 10⁻⁴ | Δ x | 5.0 × 10⁻¹ | x x | *3 |
| 7 | 26 | 70 | 4 | Yes | 4 | Yes | 6.5 × 10⁻⁴ | Δ x | 7.0 × 10⁻¹ | x x | *3 |
| 8 | 25 | 60 | 15 | Yes | 12 | Yes | 8.0 × 10⁻⁴ | Δ | 8.0 × 10⁻² | x x | *3 |
| 9 | 25 | 64 | 11 | Yes | 21 | Yes | 1.5 × 10⁻⁴ | Δ | 9.0 × 10⁻³ | Δ | *4 |
| 10 | 27 | 58 | 15 | Yes | 23 | Yes | 6.0 × 10⁻⁴ | Δ | 1.0 × 10⁻⁴ | Δ | *4 |
| 11 | 27 | 59 | 14 | Yes | 30 | Yes | 1.0 × 10⁻⁴ | ∘ | 5.0 × 10⁻³ | ∘Δ | *4 |
| 12 | 31 | 59 | 10 | Yes | 24 | Yes | 1.0 × 10⁻⁴ | ∘ | 3.5 × 10⁻⁴ | ∘Δ | *4 |
| 13 | 28 | 56 | 16 | Yes | 25 | Yes | 2.0 × 10⁻⁴ | ∘ | 5.0 × 10⁻⁴ | ∘Δ | *4 |
| 14 | 26 | 68 | 6 | Yes | 23 | Yes | 3.0 × 10⁻⁴ | ∘Δ | 8.0 × 10⁻³ | Δ | *4 |
| 15 | 27 | 57 | 16 | Yes | 33 | Yes | 6.0 × 10⁻⁵ | ∘ | 1.5 × 10⁻⁴ | ∘Δ | *4 |
| 16 | 27 | 57 | 16 | Yes | 27 | Yes | 1.0 × 10⁻⁴ | ∘ | 4.0 × 10⁻³ | ∘ | *4 |
| 17 | 25 | 61 | 14 | Yes | 43 | Yes | 8.0 × 10⁻⁵ | ∘ | 4.0 × 10⁻⁴ | ∘ | *4 |
| 18 | 28 | 56 | 16 | Yes | 36 | Yes | 5.5 × 10⁻⁵ | ∘ | 9.0 × 10⁻⁵ | ∘ | *4 |
| 19 | 26 | 60 | 14 | Yes | 38 | Yes | 7.0 × 10⁻⁵ | ∘ | 8.0 × 10⁻⁵ | ∘Δ | *4 |
| 20 | 22 | 65 | 13 | Yes | 34 | Yes | 7.0 × 10⁻⁵ | ∘ | 7.0 × 10⁻⁵ | ∘Δ | *4 |
| 21 | 26 | 59 | 15 | Yes | 40 | Yes | 4.0 × 10⁻⁵ | ∘ | 5.0 × 10⁻⁵ | ∘ | *4 |
| 22 | 27 | 58 | 15 | Yes | 40 | Yes | 1.0 × 10⁻⁵ | ∘ | 1.5 × 10⁻⁵ | ∘ | *4 |
| 23 | 28 | 57 | 15 | Yes | 39 | Yes | 4.0 × 10⁻⁵ | ∘ | 5.0 × 10⁻⁴ | ∘ | *4 |
| 24 | 27 | 53 | 14 | Yes | 38 | Yes | 3.0 × 10⁻⁶ | ∘ | 6.0 × 10⁻⁶ | ∘ | *4 |
| 25 | 28 | 56 | 16 | Yes | 38 | Yes | 3.0 × 10⁻⁶ | ∘ | 5.0 × 10⁻⁶ | ∘ | *4 |

*1: Gas barrier film No.
*2: After Conducting High temperature-high humidity treatment + Bending test
*3: Comparative example
*: 4 Present invention

As clearly shown by the results described in Table 2, the gas barrier film having a constitution stipulated in the present invention was excellent in gas barrier property (water vapor preventing property) and adhesion property compared to the comparative examples. The formed gas barrier layer did not produce cracks or peel-off even when it was subjected to a bending treatment after being kept under a high temperature and high humidity condition. It maintained the properties excellent in gas barrier property and adhesion property. It is excellent in durability.

In particular, a gas barrier film added with a reactive diluting agent in the smoothing layer, and a gas barrier film provided with a second gas barrier layer or an overcoat layer are shown to have further excellent properties.

### Example 2

### Preparation of Organic EL Element

By using gas barrier films 1 to 25 prepared in Example 1, organic EL elements 1 to 25 were prepared according to the following method as an example of an electronic device.

### [Preparation of Organic EL Element 1]

### (Formation of First Electrode Layer)

On the gas barrier film 1 prepared in Example 1, an ITO (indium tin oxide) film of 150 nm thickness was formed with a sputter method. Then, a first electrode layer was prepared by making pattering with photolithography. Here, the pattern was made so that the light emitting area became a 50 mm².

### (Formation of Hole Transport Layer)

On the first electrode layer provided with the gas barrier film 1 thus prepared was applied a coating liquid for forming a hole transport layer as described below under the conditions of 25° C. and relative humidity 50% with an extruding coater. Then, the coated layer was subjected to a drying treatment and a heating treatment to form a hole transport layer. Here, the coating liquid for forming a hole transport layer was coated with the conditions so that the dried thickness of the coated layer became 50 nm.

Before applying the coating liquid for forming a hole transport layer, the both surfaces of the gas barrier film 1 was subjected to a clean surface reforming treatment. This was done with a low pressure mercury lamp of 184.9 nm wavelength and irradiation strength of 15 mW/cm² with a distance of 10 mm. A charge removal treatment was done by using a charge removing apparatus with weak X-rays.

### <Preparation of Coating Liquid for Forming a Hole Transport Layer>

A solution of poly(ethylenedioxythiphene)-polystyrene sulfonate (PEDOT/PSS, Baytron P AI 4083 made by Bayer AG.) diluted with pure water (65%) and methanol (5%) was prepared for a coating liquid for forming a hole transport layer.

### <Drying and Heating Treatment Conditions>

After applying the coating liquid for forming a hole transport layer, the solvent was removed with a wind from a height of 100 mm from the hole transport layer coated surface with a blow speed of 1 m/s and a wind distribution in the width direction of 5% at 100° C. Then a heating treatment was done with a rear side heat transfer method at 150° C. by using a heating treatment apparatus. Thus, a hole transport layer was formed.

### (Formation of Light Emitting Layer)

On the hole transport layer formed above was applied a coating liquid for forming a white light emitting layer as described below with a extruding coater under the following conditions. Then, drying and heating treatment was done under the following conditions to obtain a light emitting layer. The coating liquid for forming a white light emitting layer was coated with the conditions so that the dried thickness of the coated layer became 40 nm.

### <Preparation of Coating Liquid for Forming a White Light Emitting Layer>

A coating liquid for forming a white light emitting layer was prepared by dissolving 1.0 g of compound H-A as a host material, 100 mg of compound D-A as a first dopant material, 0.2 mg of compound D-B as a second dopant material, and 0.2 mg of compound D-C as a third dopant material in 100 g of toluene.

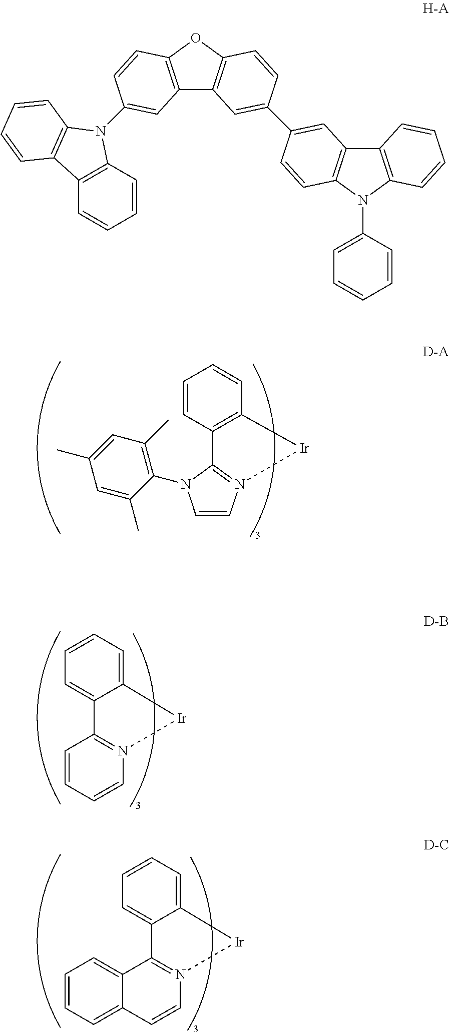

### <Coating Conditions>

The coating step was done under a nitrogen gas atmosphere having a concentration of 99% or more, at a coating temperature of 25° C. and a coating speed of 1 m/min.

### <Drying and Heating Treatment Conditions>

After applying the coating liquid for forming a white light emitting layer on the hole transport layer, the solvent was removed with a wind from a height of 100 mm from the coated surface with a blow speed of 1 m/s and a wind distribution in the width direction of 5% at 60° C. Then a heating treatment was done at 130° C. Thus, a light emitting layer was formed.

### (Formation of Electron Transport Layer)

On the light emitting layer formed above was applied a coating liquid for forming an electron transport layer as described below with a extruding coater under the following conditions. Then, drying and heating treatment was done under the following conditions to obtain an electron transport layer. The coating liquid for forming an electron transport layer was coated with the conditions so that the dried thickness of the coated layer became 30 nm.

### <Preparation of Coating Liquid for Forming an Electron Transport Layer>

A coating liquid for forming an electron transport layer was prepared by dissolving the following compound E-A in 2,2,3,3-tetrafluoro-1-propanol to obtain 0.5 mass % solution.

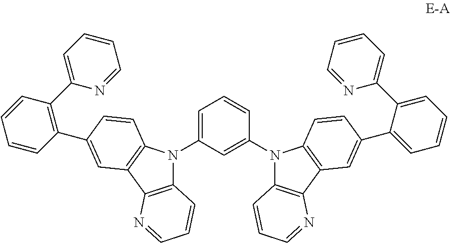 [SMILES: c1ccc(-c2ccccc2-c2ccc3c(c2)c2ncccc2n3-c2cccc(-n3c4ccc(-c5ccccc5-c5ccccn5)cc4c4ncccc43)c2)nc1]

### <Coating Conditions>

The coating step was done under a nitrogen gas atmosphere having a concentration of 99% or more, at a coating temperature of a coating liquid for forming an electron transport layer to be 25° C. and a coating speed of 1 m/min.

### <Drying and Heating Treatment Conditions>

After applying the coating liquid for forming an electron transport layer on the light emitting layer, the solvent was removed with a wind from a height of 100 mm from the coated surface with a blow speed of 1 m/s and a wind distribution in the width direction of 5% at 60° C. Then a heating treatment was done at 200° C. Thus, an electron transport layer was formed.

### (Formation of Electron Injection Layer)

On the electron transport layer formed above was formed an electron injection layer in accordance with the following method.

The gas barrier film 1 which was formed with an electron transport layer was placed into a reduced pressure chamber, and the pressure of the reduced pressure chamber was reduced to 5×10⁻⁴ Pa. Cesium fluoride contained in a tantalum vapor deposition boat placed in the vacuum chamber was heated. An electron injection layer having a thickness of 3 nm was formed.

### (Formation of Second Electrode)

On the formed electron injection except the portion to become a taking out electrode of the first electrode was formed a mask patterned film of aluminum so that it has a taking out electrode and has a lighting area to be 50 mm² with a vapor deposition method under 5×10⁻⁴ Pa. Thus, it was formed a second electrode having a thickness of 100 nm.

### (Cutting)

The laminate body formed with till the second electrode as described above was transported again in a nitrogen atmosphere, and it was cut to a predetermined size with a UV laser to produce an organic EL element 1.

### (Connection of Electrode Lead)

The produced organic EL element 1 was connected to a flexible print substrate (base film: polyimide of 12.5 μm, rolled copper foil of 18 μm, cover lay: polyimide of 12.5 μm, surface treatment with NiAu plating) with an anisotropic conductive film DP3232S9 (made bay Sony Chemical & Information Device Co. Ltd.).

It was pressure bonded with pressure bonding conditions of: temperature of 170° C. (AFC temperature of 140° C. separately measured with a thermocouple), pressure of 2 MPa, for 10 seconds.

### (Sealing)

As a sealing member, it was prepared a laminate body having an aluminum foil having a thickness of 30 μm (made of Toyo Aluminum K.K.) laminated with a polyethylene terephthalate (PET) film (12 μm thickness) with a dry lamination adhesive (2 liquid reactive type urethane adhesive, the thickness of the adhesive being 1.5 μm).

On the aluminum surface of the prepared sealing member was coated a heat curable adhesive with a dispenser so that the thickness of the adhesive became 20 μm and uniform along the bonded surface of the aluminum foil (luster surface). Thus, an adhesive layer was formed.

At this time, a mixed epoxy adhesive of the following (A) to (C) was used as a heat curable adhesive.

(A) Bisphenol A diglycidyl ether (DGEBA)

(B) Dicyandiamide (DICY)

(C) Epoxy adduct type curing accelerator

The sealing member was placed in an arrangement of closely covering the connecting portion of the taking out electrodes and the electrode leads. Using a pressure roller, it was closely sealed with conditions of: pressure roller temperature of 120° C., pressure of 0.5 MPa, and speed of the apparatus of 0.3 m/min.

### [Preparation of Organic EL Elements 2 to 25]

The organic EL elements 2 to 25 were prepared in the same way as preparation of the aforesaid organic EL element 1 except that the gas barrier film 1 was replaced with the gas barrier films 2 to 25 prepared in Example 1.

### <<Evaluation of Organic EL Element>>

The prepared organic EL elements 1 to 25 were subjected to durability evaluation in accordance with the following method.

### [Evaluation of Durability]

### (Accelerated Degradation Treatment)

Each of the prepared organic EL elements was subjected to an accelerated degradation treatment at 60° C. and 90% RH for 400 hours. It was evaluated with respect to black spot as indicated below with an organic EL element without subjected to an accelerated degradation treatment.

### (Measurement of Number of Black Spots and Evaluation of Durability)

To the organic EL element with an accelerated degradation treatment and the organic EL element without an accelerated degradation treatment (blank sample) each were applied electric current of 1 mA/cm² and light emission was done for 24 hours. After that, a part of the panel was magnified with a microscope of 100 times magnification (MS-804, lens P-ZE25-200, made of Moritecs Co. Ltd.) and the picture was taken. The obtained image was divided into a square of 2 mm. The ratio of the produced area of black spots was obtained and a degradation resistance ratio of the element was calculated according to the following scheme.

Subsequently, durability was evaluated according to the following criteria based on the obtained degradation resistance ratio of the element. When the evaluation rank was ⊚ or ◯, it was concluded that the sample had a preferable property for practical use.

Degradation resistance ratio of the element=(Area of black spots in the element without being subjected to an accelerated degradation treatment/Area of black spots in the element with being subjected to an accelerated degradation treatment)×100(%)

⊚: Degradation resistance ratio of the element is 90% or more

◯: Degradation resistance ratio of the element is from 75% or more to less than 90%

Δ: Degradation resistance ratio of the element is from 60% or more to less than 75%

ΔX: Degradation resistance ratio of the element is from 45% or more to less than 60%

X: Degradation resistance ratio of the element is less than 45%.

TABLE 3

| | Evaluation of | |
|---|---|---|
| Gas barrier film No. | Organic EL element | Remarks |
| 1 | X | Comparative example |
| 2 | X | Comparative example |
| 3 | ΔX | Comparative example |
| 4 | X | Comparative example |
| 5 | ΔX | Comparative example |
| 6 | X | Comparative example |
| 7 | X | Comparative example |
| 8 | X | Comparative example |
| 9 | Δ | Present invention |
| 10 | Δ | Present invention |
| 11 | ◯ | Present invention |
| 12 | ◯ | Present invention |
| 13 | ◯ | Present invention |
| 14 | ◯ | Present invention |
| 15 | ◯ | Present invention |
| 16 | ◯ | Present invention |
| 17 | ◯ | Present invention |
| 18 | ◯ | Present invention |
| 19 | ⊚ | Present invention |
| 20 | ⊚ | Present invention |
| 21 | ⊚ | Present invention |
| 22 | ⊚ | Present invention |
| 23 | ⊚ | Present invention |
| 24 | ⊚ | Present invention |
| 25 | ⊚ | Present invention |

As clearly shown by the results described in Table 3, an organic EL element provided with a gas barrier film of the present invention has a degradation resistance ratio of the element of 75% or more. It is shown that it had an excellent durability. On the other hand, an organic EL element provided with a gas barrier film of the comparative example had a degradation resistance ratio of the element of less than 60%.

Consequently, it can be seen that the gas barrier film described in Example of the present invention has an excellent gas barrier property which can be applied to a resin substrate or a sealing film of an organic EL element that is an electronic device.

Moreover, it can be seen that: an organic EL element using a gas barrier film containing a reactive diluting agent in a smoothing layer; or an organic EL element provided with a second gas barrier layer or an overcoat layer has further excellent property.

### INDUSTRIAL APPLICABILITY

A production method of a gas barrier film of the present invention is a method enabling to produce a gas barrier film having a gas barrier property required for electronic device applications, and excellent in flexibility and adhesion property. The gas barrier film produced by the method of the present invention is suitably used for an organic electroluminescent panel (organic EL panel), an organic electroluminescent element (organic EL element), an organic photoelectron conversion element and a liquid crystal element.

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

### DESCRIPTION OF SYMBOLS

1: Gas barrier film
2: Resin substrate
3: Smoothing layer
4: Gas barrier layer
5: Second gas barrier layer
6: Transparent electrode
7: Organic EL element (Electronic device main body)
8: Adhesive layer
9: Opposing film
P: Organic EL panel (Electronic device)
11: Delivery roller
21, 22, 23 and 24: Conveyer roller
31 and 32: Deposition roller
41: Gas inlet
51: Power source for plasma generation
61 and 62: Magnetic-field generator
71: Reeling roller
A: Carbon distribution curve
B: Silicon distribution curve
C: Oxygen distribution curve
D: Oxygen-carbon distribution curve

1. A method for producing a gas barrier film comprising:
forming a smoothing layer on one surface of a resin substrate; and
forming a gas barrier layer containing a carbon atom, a silicon atom and an oxygen atom on a surface of the smoothing layer,
wherein the surface of the smoothing layer is controlled to have a dispersion component of a surface free energy in the range of 30 to 40 mN/m at an environment of 23° C. and 50% RH; and
the gas barrier layer is formed employing a raw material gas containing an organic silicon compound and an oxygen gas with a discharge plasma chemical vapor deposition method having a discharge space between rollers applied with a magnetic field.

2. The method for producing a gas barrier film described in claim 1,
wherein the gas barrier layer is formed so as to satisfy all of the following conditions (1) to (4),
(1) a carbon atomic ratio of the gas barrier layer is continuously changed in a thickness direction in relation to a distance from a surface of the gas barrier layer within a distance range of 89% from the surface of the gas barrier layer when a thickness of the gas barrier layer in a vertical direction is set to be 100%,
(2) a maximum value of the carbon atomic ratio of the gas barrier layer in the thickness direction is less than 20 at % within the distance range of 89% from the surface of the gas barrier layer when the thickness of the gas barrier layer in a vertical direction is set to be 100%,
(3) a carbon atomic ratio of the gas barrier layer is continuously increased in the thickness direction within the distance range of 90 to 95% from the surface of the gas barrier layer when the thickness of the gas barrier layer in a vertical direction is set to be 100%,
(4) a maximum value of the carbon atomic ratio of the gas barrier layer in the thickness direction is 20 at % or more within the distance range of 90 to 95% from the surface of the gas barrier layer when the thickness of the gas barrier layer in a vertical direction is set to be 100%.

3. The method for producing a gas barrier film described in claim 1,
wherein the smoothing layer is formed by coating a composition containing a resin having a radical reactive unsaturated bond, an inorganic particle, a photo-initiator, a solvent, and a reactive diluting agent; and
a ratio of the reactive diluting agent in the smoothing layer is in the range of 0.1 to 10 mass %.

4. The method for producing a gas barrier film described in claim 1,
wherein a second gas barrier layer is formed by coating a polysilazane containing liquid on the gas barrier layer, followed by drying to form a coated film, then the coated film is subjected to a reforming treatment by irradiating with vacuum ultraviolet rays having a wavelength of 200 nm or less.

5. A gas barrier film comprising: a smoothing layer on one surface of a resin substrate; and a gas barrier layer containing a carbon atom, a silicon atom and an oxygen atom on a surface of the smoothing layer,
wherein a surface of the smoothing layer has a dispersion component of a surface free energy in the range of 30 to 40 mN/m at an environment of 23° C. and 50% RH; and
the gas barrier layer is formed employing a raw material gas containing an organic silicon compound and an oxygen gas with a discharge plasma chemical vapor deposition method having a discharge space between rollers applied with a magnetic field.

6. A gas barrier film described in claim 5, satisfying all of the following conditions (1) to (4),
(1) a carbon atomic ratio of the gas barrier layer is continuously changed in a thickness direction in relation to a distance from a surface of the gas barrier layer within a distance range of 89% from the surface of the gas barrier layer when a thickness of the gas barrier layer in a vertical direction is set to be 100%,
(2) a maximum value of the carbon atomic ratio of the gas barrier layer in the thickness direction is less than 20 at % within the distance range of 89% from the surface of the gas barrier layer when the thickness of the gas barrier layer in a vertical direction is set to be 100%,
(3) a carbon atomic ratio of the gas barrier layer is continuously increased in the thickness direction within the distance range of 90 to 95% from the surface of the gas barrier layer when the thickness of the gas barrier layer in a vertical direction is set to be 100%,
(4) a maximum value of the carbon atomic ratio of the gas barrier layer in the thickness direction is 20 at % or more within the distance range of 90 to 95% from the surface of the gas barrier layer when the thickness of the gas barrier layer in a vertical direction is set to be 100%.

7. An electronic device provided with the gas barrier film described in claim 5.
